(19) United States
(12) Patent Application Publication
(10) Pub. No.: US 2025/0142813 A1
(43) Pub. Date: May 1, 2025

(54) SEMICONDUCTOR MEMORY DEVICE

(71) Applicant: Samsung Electronics Co., Ltd., Suwon-si (KR)

(72) Inventors: Soo Ho SHIN, Suwon-si (KR); Ji Hoon CHANG, Suwon-si (KR); Ga Eun LEE, Suwon-si (KR); Hyeon-Woo JANG, Suwon-si (KR)

(21) Appl. No.: 18/648,797

(22) Filed: Apr. 29, 2024

(30) Foreign Application Priority Data
Oct. 26, 2023 (KR) 10-2023-0144457

(51) Int. Cl. H10B 12/00; H01L 23/528; H01L 29/51

(52) U.S. Cl. CPC H10B 12/50; H01L 23/5283; H10B 12/315; H10B 12/482; H10D 64/693

(57) ABSTRACT

A semiconductor memory device includes a substrate including a cell area and a peripheral area defined around the cell area, a peripheral gate on the peripheral area and including a peripheral gate conductive film, peripheral wiring lines on the peripheral gate, peripheral wiring capping films respectively in contact with the peripheral wiring lines, wherein each peripheral wiring capping film includes upper and lower surfaces, and a peripheral wiring isolation pattern isolating adjacent peripheral wiring lines, and contacting a sidewall of the peripheral wiring lines, wherein the lower surface of each peripheral wiring capping film faces the substrate and contacts an upper surface of the peripheral wiring extension line, wherein a height from an upper surface of the substrate to the upper surface of each peripheral wiring extension line is smaller than a height from the upper surface of the substrate to an upper surface of the peripheral wiring isolation pattern.

### CROSS-REFERENCE TO RELATED APPLICATION

This application claims priority from Korean Patent Application No. 10-2023-0144457 filed on Oct. 26, 2023 in the Korean Intellectual Property Office, and all the benefits accruing therefrom under 35 U.S.C. 119, the contents of which in its entirety are herein incorporated by reference.

### BACKGROUND

### Field

The present disclosure relates to a semiconductor memory device, and more specifically, to a semiconductor memory device having multiple wiring lines intersecting with each other, and buried contacts.

### Description of Related Art

As a semiconductor device becomes increasingly highly integrated, individual circuit patterns are becoming smaller in order to implement a larger number of semiconductor devices in the same area. That is, as integration of the semiconductor device increases, a design rule on each of components of the semiconductor device decreases.

In a highly scaled semiconductor device, a process of forming a plurality of wiring lines and a plurality of buried contacts (BC) interposed therebetween is becoming increasingly complicated and sophisticated.

### SUMMARY

A technical purpose to be achieved by the present disclosure is to provide a semiconductor memory device having improved reliability and performance.

Purposes according to the present disclosure are not limited to the above-mentioned purpose. Other purposes and advantages according to the present disclosure that are not mentioned may be understood based on following descriptions, and may be more clearly understood based on embodiments according to the present disclosure. Further, it will be easily understood that the purposes and advantages according to the present disclosure may be realized using means shown in the claims or combinations thereof.

According to an aspect of the present disclosure, there is provided a semiconductor device comprising a substrate including a cell area and a peripheral area defined around the cell area, wherein the cell area includes a cell active area defined by a cell element isolation film; a bit-line on the cell area of the substrate; a peripheral gate on the peripheral area of the substrate, the peripheral gate including a peripheral gate conductive film; peripheral wiring lines on the peripheral gate, wherein each of the peripheral wiring lines includes a peripheral wiring extension line made of a metal; peripheral wiring capping films respectively in contact with the peripheral wiring extension lines, wherein each of the peripheral wiring capping films includes an upper surface and a lower surface opposite to the upper surface; and a peripheral wiring isolation pattern isolating adjacent peripheral wiring lines from each other, and contacting sidewalls of the isolated peripheral wiring lines, wherein the lower surface of each of the peripheral wiring capping films faces the substrate and contacts an upper surface of a respective peripheral wiring extension line, and wherein a height from an upper surface of the substrate to the upper surface of each of the peripheral wiring extension lines is smaller than a height from the upper surface of the substrate to an upper surface of the peripheral wiring isolation pattern.

According to an aspect of the present disclosure, there is provided a semiconductor memory device comprising a substrate including a cell area and a peripheral area defined around the cell area, wherein the cell area includes a cell active area defined by a cell element isolation film; a bit-line on the cell area of the substrate; a peripheral gate on the peripheral area of the substrate, the peripheral gate including a peripheral gate conductive film; peripheral wiring lines on the peripheral gate, wherein each of the peripheral wiring lines includes a peripheral wiring extension line made of a metal; peripheral wiring capping films respectively in contact with the peripheral wiring extension lines, wherein each of the peripheral wiring capping films includes an upper surface and a lower surface opposite to the upper surface; and a peripheral wiring isolation pattern isolating adjacent peripheral wiring lines from each other, and contacting sidewalls of the isolated peripheral wiring lines, wherein the lower surface of each of the peripheral wiring capping films faces the substrate and contacts an upper surface of a respective peripheral wiring extension line without contacting an upper surface of the peripheral wiring isolation pattern.

According to an aspect of the present disclosure, there is provided a semiconductor memory device comprising a substrate including a cell area and a peripheral area defined around the cell area, wherein the cell area includes a cell active area defined by a cell element isolation film; a bit-line on the cell area of the substrate; a peripheral gate on the peripheral area of the substrate, the peripheral gate including a peripheral gate conductive film; peripheral wiring lines on the peripheral gate, wherein each of the peripheral wiring lines includes a peripheral wiring extension line made of a metal; peripheral wiring capping films respectively in contact with the peripheral wiring extension lines, wherein each of the peripheral wiring capping films includes an upper surface and a lower surface opposite to the upper surface; a peripheral wiring isolation pattern isolating adjacent peripheral wiring lines from each other, and contacting sidewalls of the isolated peripheral wiring lines, storage contacts connected to the cell active area; storage pads connected to the storage contact, wherein each of the storage pads includes a storage pad plug film, wherein each of the storage pad plug films is made of the same metal as the metal of the peripheral wiring extension lines; a pad isolation pattern isolating adjacent storage pads from each other; an etch stop film extending along an upper surface of the peripheral wiring isolation pattern, the upper surface of each of the peripheral wiring capping films, and an upper surface of the pad isolation pattern; and a data storage pattern extending through the etch stop film to be connected to the storage pad plug films, wherein the lower surface of each of the peripheral wiring capping films faces the substrate and contacts an upper surface of a respective peripheral wiring extension line, and wherein a height from an upper surface of the substrate to the upper surface of each of the peripheral wiring capping films is equal to a height from the upper surface of the substrate to the upper surface of the peripheral wiring isolation pattern.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

### BRIEF DESCRIPTION OF DRAWINGS

The above and other aspects and features of the present disclosure will become more apparent by describing in detail some embodiments thereof with reference to the attached drawings, in which:

FIG. 1 is a schematic layout diagram of a semiconductor memory device according to some embodiments.

FIG. 2 is a layout diagram of an area R as a portion of a cell area in FIG. 1.

FIG. 3 is a layout diagram showing only a word-line and an active area of FIG. 2.

FIG. 4 is a cross-sectional view cut along a line A-A in FIG. 1.

FIG. 5 and FIG. 6 are cross-sectional views taken along lines B-B and C-C of FIG. 2, respectively.

FIG. 7 and FIG. 8 are respectively enlarged views of a P portion of FIG. 4.

FIG. 9 to FIG. 11 are diagrams for illustrating a semiconductor memory device according to some embodiments.

FIG. 12 is a diagram for illustrating a semiconductor memory device according to some embodiments.

FIG. 13 to FIG. 16 are diagrams for illustrating a semiconductor memory device according to some embodiments.

FIG. 17 to FIG. 19 are diagrams for illustrating a semiconductor memory device according to some embodiments.

FIG. 20 and FIG. 21 are diagrams for illustrating a semiconductor memory device according to some embodiments.

FIG. 22 is a diagram for illustrating a semiconductor memory device according to some embodiments.

FIG. 23 is a diagram for illustrating a semiconductor memory device according to some embodiments.

FIG. 24 is a cross-sectional view cut along lines D-D and E-E of FIG. 22.

FIG. 25 is a layout diagram for illustrating a semiconductor memory device according to some embodiments.

FIG. 26 is a perspective view for illustrating a semiconductor memory device according to some embodiments.

FIG. 27 is a diagram for illustrating a semiconductor memory device according to some embodiments.

FIG. 28 to FIG. 34 are diagrams of intermediate structures corresponding to intermediate steps for illustrating a method for manufacturing a semiconductor memory device according to some embodiments.

FIG. 35 and FIG. 36 are diagrams of intermediate structures corresponding to intermediate steps of a semiconductor memory device manufacturing method according to some embodiments.

### DETAILED DESCRIPTIONS

Advantages and features of the present disclosure, and a method of achieving the advantages and features will become apparent with reference to embodiments described later in detail together with the accompanying drawings. However, embodiments of the present disclosure are not limited to the embodiments as disclosed herein, but may be implemented in various different forms. Thus, these embodiments are set forth only to make the present disclosure complete, and to completely inform the scope of the present disclosure to those of ordinary skill in the technical field to which the present disclosure belongs.

For simplicity and clarity of illustration, elements in the drawings are not necessarily drawn to scale. The same reference numbers in different drawings represent the same or similar elements, and as such perform similar functionality. Further, descriptions and details of well-known steps and elements are omitted for simplicity of the description. Furthermore, in the following detailed description of the present disclosure, numerous specific details are set forth in order to provide a thorough understanding of the present disclosure. However, it will be understood that the present disclosure may be practiced without these specific details. In other instances, well-known methods, procedures, components, and circuits have not been described in detail so as not to unnecessarily obscure aspects of the present disclosure. Examples of various embodiments are illustrated and described further below. It will be understood that the description herein is not intended to limit the claims to the specific embodiments described. On the contrary, it is intended to cover alternatives, modifications, and equivalents as may be included within the spirit and scope of the present disclosure as defined by the appended claims.

A shape, a size, a ratio, an angle, a number, etc. disclosed in the drawings for illustrating embodiments of the present disclosure are illustrative, and an embodiment of embodiments of the present disclosure are not limited thereto.

The terminology used herein is directed to the purpose of describing particular embodiments only and is not intended to be limiting of the present disclosure. As used herein, the singular constitutes “a” and “an” are intended to include the plural constitutes as well, unless the context clearly indicates otherwise. It will be further understood that the terms “comprise”, “comprising”, “include”, and “including” when used in this specification, specify the presence of the stated features, integers, operations, elements, and/or components, but do not preclude the presence or addition of one or more other features, integers, operations, elements, components, and/or portions thereof. As used herein, the term “and/or” includes any and all combinations of one or more of associated listed items. Expression such as “at least one of” when preceding a list of elements may modify the entire list of elements and may not modify the individual elements of the list. In interpretation of numerical values, an error or tolerance therein may occur even when there is no explicit description thereof.

It will also be understood that when a first element or layer is referred to as being present “on” a second element or layer, the first element may be disposed directly on the second element or may be disposed indirectly on the second element with a third element or layer being disposed between the first and second elements or layers. It will also be understood that when a first element or layer is referred to as being present “under” a second element or layer, the first element may be disposed directly under the second element or may be disposed indirectly under the second element with a third element or layer being disposed between the first and second elements or layers.

It will be understood that when an element or layer is referred to as being “connected to”, or “coupled to” another element or layer, it may be directly connected to or coupled to another element or layer, or one or more intervening elements or layers therebetween may be present.

In addition, it will also be understood that when an element or layer is referred to as being “between” two elements or layers, it may be the only element or layer between the two elements or layers, or one or more intervening elements or layers therebetween may also be present.

Further, as used herein, when a layer, film, region, plate, or the like is disposed “on” or “on a top” of another layer, film, region, plate, or the like, the former may contact the latter or still another layer, film, region, plate, or the like may be disposed between the former and the latter. As used herein, when a layer, film, region, plate, or the like is “directly” disposed “on” or “on a top” of another layer, film, region, plate, or the like, the former contacts the latter and still another layer, film, region, plate, or the like is not disposed between the former and the latter. Further, as used herein, when a layer, film, region, plate, or the like is disposed “below” or “under” another layer, film, region, plate, or the like, the former may contact the latter or still another layer, film, region, plate, or the like may be disposed between the former and the latter. As used herein, when a layer, film, region, plate, or the like is “directly” disposed “below” or “under” another layer, film, region, plate, or the like, the former contacts the latter and still another layer, film, region, plate, or the like is not disposed between the former and the latter.

In descriptions of temporal relationships, for example, temporal precedent relationships between two events such as “after”, “subsequent to”, “before”, etc., another event may occur therebetween unless “directly after”, “directly subsequent” or “directly before” is indicated.

When a certain embodiment may be implemented differently, a function or an operation specified in a specific block may occur in a different order from an order specified in a flowchart. For example, two blocks in succession may be actually performed substantially concurrently, or the two blocks may be performed in a reverse order depending on a function or operation involved.

It will be understood that, although the terms “first”, “second”, “third”, and so on may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described under could be termed a second element, component, region, layer or section, without departing from the spirit and scope of the present disclosure.

Spatially relative terms, such as “beneath,” “below,” “lower,” “under,” “above,” “upper,” and the like, may be used herein for ease of illustration to illustrate one element or feature's relationship to another element or feature as illustrated in the figures. It will be understood that the spatially relative terms are intended to encompass different orientations of the device in use or in operation, in addition to the orientation depicted in the figures. For example, when the device in the drawings may be turned over, elements described as “below” or “beneath” or “under” other elements or features would then be oriented “above” the other elements or features. Thus, the example terms “below” and “under” may encompass both an orientation of above and below. The device may be otherwise oriented, for example, rotated 90 degrees or at other orientations, and the spatially relative descriptors used herein should be interpreted accordingly.

The features of the various embodiments of the present disclosure may be partially or entirely combined with each other, and may be technically associated with each other or operate with each other. The embodiments may be implemented independently of each other and may be implemented together in an association relationship.

In interpreting a numerical value, the value is interpreted as including an error range unless there is an explicit description thereof to the contrary.

Unless otherwise defined, all terms including technical and scientific terms used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

As used herein, “embodiments,” “examples,” “aspects,” and the like should not be construed such that any aspect or design as described is superior to or advantageous over other aspects or designs.

Further, the term ‘or’ means ‘inclusive or’ rather than ‘exclusive or’. That is, unless otherwise stated or clear from the context, the expression that ‘x uses a or b’ means any one of natural inclusive permutations.

The terms used in the description below have been selected as being general and universal in the related technical field. However, there may be other terms than the terms depending on the development and/or change of technology, convention, preference of technicians, etc. Therefore, the terms used in the description below should not be understood as limiting technical ideas, but should be understood as examples of the terms for illustrating embodiments.

Further, in a specific case, a term may be arbitrarily selected by the applicant, and in this case, the detailed meaning thereof will be described in a corresponding description section. Therefore, the terms used in the description below should be understood based on not simply the name of the terms, but the meaning of the terms and the contents throughout the present disclosure.

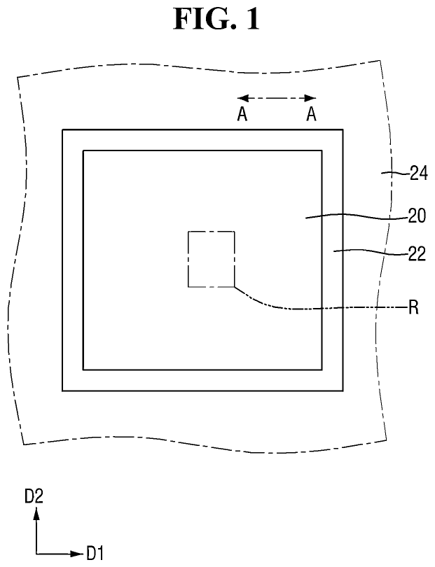

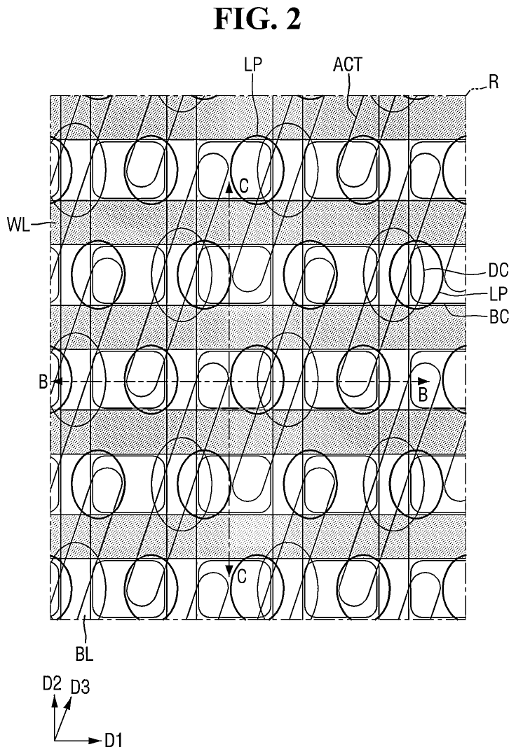

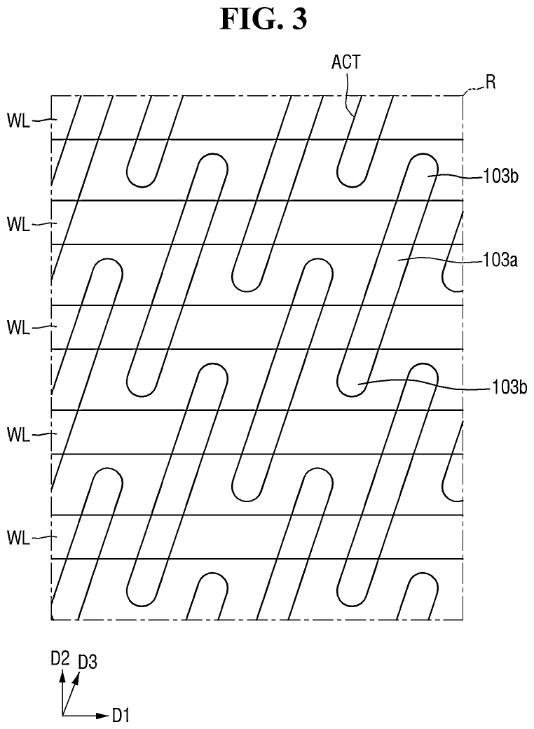

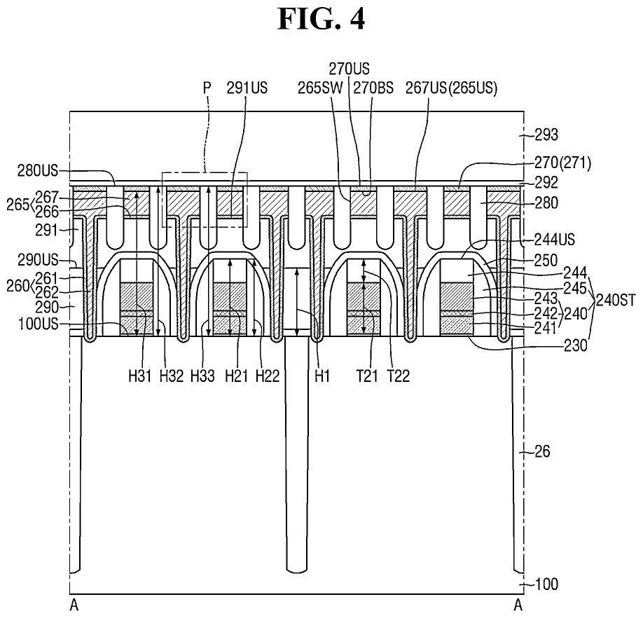

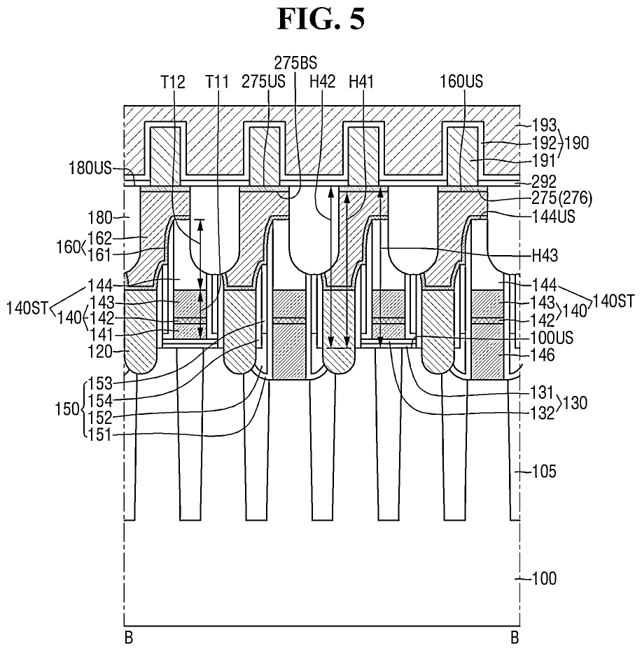

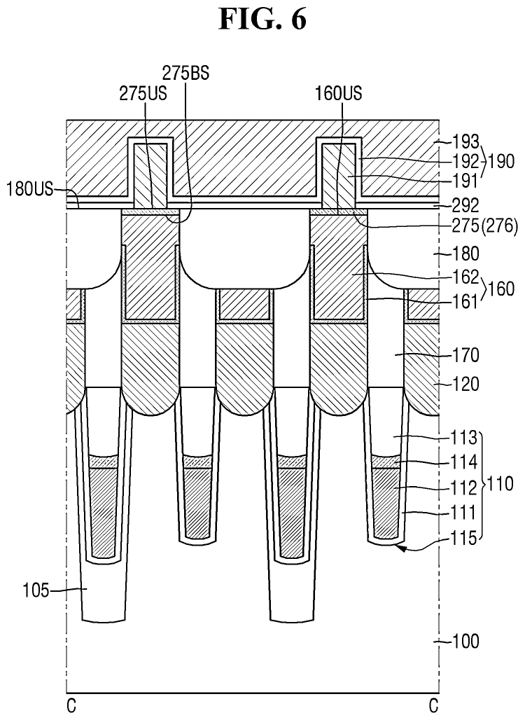

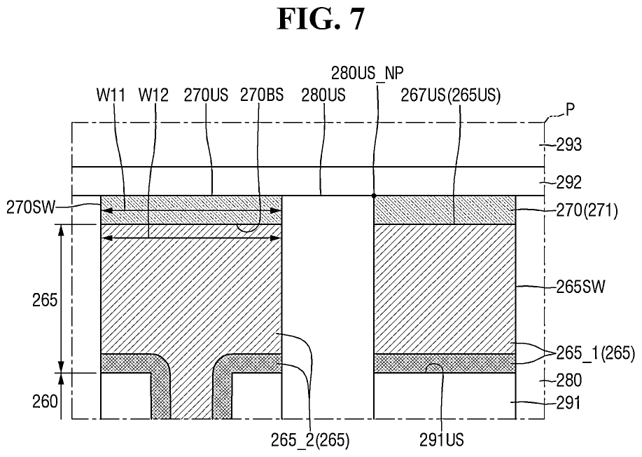

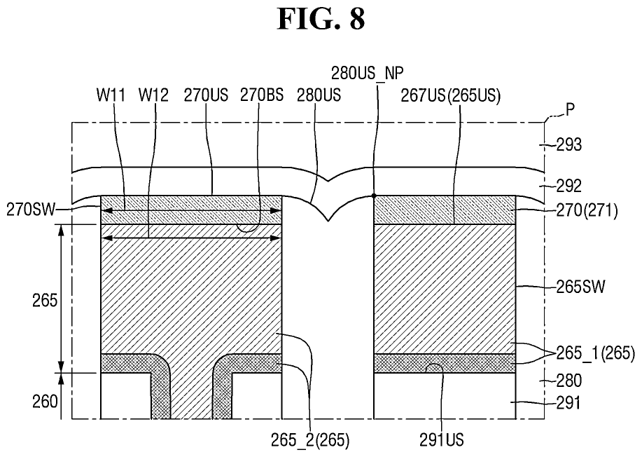

FIG. 1 is a schematic layout diagram of a semiconductor memory device according to some embodiments. FIG. 2 is a layout diagram of an area R as a portion of a cell area in FIG. 1. FIG. 3 is a layout diagram showing only a word-line and an active area of FIG. 2. FIG. 4 is a cross-sectional view cut along a line A-A in FIG. 1. FIG. 5 and FIG. 6 are cross-sectional views taken along lines B-B and C-C of FIG. 2, respectively. FIG. 7 and FIG. 8 are respectively enlarged views of a P portion of FIG. 4.

For reference, FIG. 4 may be an illustrative cross-sectional view of a transistor formation area in a peripheral area. In FIG. 1, the line A-A is shown as extending along a first direction D1. However, embodiments of the present disclosure are not limited thereto. Unlike what is shown, the line A-A may extend along a second direction D2.

In the drawing of the semiconductor memory device according to some embodiments, a DRAM (dynamic random access memory) is shown by way example. However, embodiments of the present disclosure are not limited thereto.

Referring to FIG. 1 to FIG. 3, the semiconductor memory device according to some embodiments may include a cell area 20, the cell area isolation film 22, and a peripheral area 24.

The cell area isolation film 22 may be disposed around the cell area 20. The cell area isolation film 22 may isolate the cell area 20 and the peripheral area 24 from each other. The peripheral area 24 may be defined around the cell area 20.

The cell area 20 may include a plurality of the cell active areas ACT. The cell active area ACT may be defined by a cell element isolation film (105 of FIG. 5) formed in a substrate (100 of FIG. 5). As a design rule of a semiconductor memory device decreases, the cell active area ACT may extend in a bar shape of a diagonal line or an oblique line. For example, the cell active area ACT may extend in a third direction D3 as shown, e.g., in FIG. 3.

A plurality of gate electrodes may extend in a first direction D1 and across the cell active area ACT. The plurality of gate electrodes may extend in a parallel manner to each other. The plurality of gate electrodes may be, for example, a plurality of word-lines WL. The word-lines WL may be arranged so as to be spaced from each other at an equal spacing. A width of the word-line WL and/or the spacing between the word-lines WL may be determined based on the design rule.

Two word-lines WL extending in the first direction D1 may divide each cell active area ACT into 3 portions. The cell active area ACT may include a bit-line connection area 103a and a storage connection area 103b. The bit-line connection area 103a may be located in a middle portion of the cell active area ACT, and the storage connection area 103b may be located at an end of the cell active area ACT.

A plurality of bit-lines BL extending in a second direction D2 and orthogonal to the word-line WL may be disposed on the word-line WL. The plurality of bit-lines BL may extend in a parallel manner to each other. The bit-lines BL may be arranged so as to be spaced from each other at an equal spacing. A width of the bit-line BL and/or the spacing between the bit-lines BL may be determined based on the design rule.

The semiconductor memory device according to some embodiments may include various contact arrays formed on the cell active area ACT. The various contact arrangements may include, for example, a direct contact (DC), a buried contact (BC), and a landing pad (LP).

In this regard, the direct contact DC may mean a contact electrically connecting the cell active area ACT to the bit-line BL. The buried contact BC may mean a contact that connects the cell active area ACT to a first lower electrode (191 of FIG. 5) of a capacitor. Due to a layout structure, a contact area between the buried contact BC and the cell active area ACT may be small. Accordingly, in order to increase the contact area between the buried contact BC and the cell active area ACT and a contact area between the buried contact BC and the first lower electrode (191 of FIG. 5) of the capacitor, a conductive landing pad LP may be introduced.

The landing pad LP may be disposed may be disposed between the buried contact BC and the first lower electrode (191 of FIG. 5) of the capacitor and may be disposed between the cell active area ACT and the buried contact BC. In the semiconductor memory device according to some embodiments, the landing pad LP may be disposed between the buried contact BC and the first lower electrode (191 of FIG. 5) of the capacitor. The contact area may increase due to the introduction of the landing pad LP, such that a contact resistance between the cell active area ACT and the first lower electrode (191 of FIG. 5) of the capacitor may be reduced.

The direct contact DC may be connected to the bit-line connection area 103a. The buried contact BC may be connected to the storage connection area 103b. As the buried contact BC is disposed at each of both opposing ends of the cell active area ACT, the landing pad LP may be disposed adjacent to each of both opposing ends of the cell active area ACT so as to partially overlap the buried contact BC. In other words, the buried contact BC may be formed to overlap a portion of each of the cell active area ACT and the cell element isolation film (105 of FIG. 5) disposed between adjacent word-lines WL and between adjacent bit-lines BL.

The word-line WL may be formed as a structure buried in the substrate 100. The word-line WL may extend across a portion of the cell active area ACT disposed between the direct contacts DC or the buried contacts BC. As shown, two word-lines WL may intersect one cell active area ACT. As the cell active area ACT extends along the third direction D3, the word-line WL may define an angle smaller than 90 degrees relative to the cell active area ACT.

The direct contacts DC may be arranged symmetrically. The buried contacts BC may be arranged symmetrically. Thus, the direct contacts DC may be arranged in a straight line along each of the first direction D1 and the second direction D2. The buried contacts BC may be arranged in a straight line along each of the first direction D1 and the second direction D2. In one example, unlike the direct contact DC and the buried contact BC, the landing pads LP may be arranged in a zigzag pattern along the second direction D2 in which the bit-line BL extends. Further, the landing pads LP may respectively overlap the same side faces of the bit-lines BL arranged in the first direction D1 in which the word-line WL extends. For example, the landing pads LP of a first line that extends in the first direction D1 may respectively overlap left side faces of corresponding bit-lines BL, while the landing pads LP of a second line that extends in the first direction D1 may respectively overlap right side faces of corresponding bit-lines BL.

Referring to FIG. 1 to FIG. 8, the semiconductor memory device according to some embodiments may include a plurality of the cell gate structures 110, a plurality of bit-line structures 140ST, a plurality of storage contacts 120, a plurality of storage pads 160, a data storage pattern 190, a peripheral gate structure 240ST, a peripheral wiring line 265, and a peripheral wiring capping film 270.

The substrate 100 may include the cell area 20, the cell area isolation film 22, and the peripheral area 24. The substrate 100 may be a silicon substrate or an SOI (silicon-on-insulator) substrate. Alternatively, the substrate 100 may be formed of or include, but is not limited to, silicon germanium, SGOI (silicon germanium on insulator), indium antimonide, a lead telluride compound, indium arsenide, indium phosphide, gallium arsenide, or gallium antimonide.

The plurality of the cell gate structures 110, the plurality of bit-line structures 140ST, the plurality of storage contacts 120, the plurality of storage pads 160, and the data storage pattern 190 may be disposed in the cell area 20. The peripheral gate structure 240ST, the peripheral wiring line 265, and the peripheral wiring capping film 270 may be disposed in the peripheral area 24.

The cell element isolation film 105 may be formed in the cell area 20 of the substrate 100. The cell element isolation film 105 may have an STI (shallow trench isolation) structure having excellent element isolation ability. The cell element isolation film 105 may define the cell active area ACT in the cell area 20. As shown in FIG. 2 and FIG. 3, the cell active area ACT defined by the cell element isolation film 105 may have an elongate island shape including a short side and a long side. The cell active area ACT may extend in the diagonal direction so as to define an angle smaller than 90 degrees with respect to the direction of extension of the word-line WL formed in the cell element isolation film 105. Further, the cell active area ACT may extend in the diagonal direction so as to define an angle smaller than 90 degrees with respect to the direction of extension of the bit-line BL disposed on the cell element isolation film 105.

The cell area isolation film 22 may be embodied as a cell boundary isolation film having an STI structure. The cell area 20 may be defined by the cell area isolation film 22.

Each of the cell clement isolation film 105 and the cell area isolation film 22 may be formed of or include, for example, at least one of a silicon oxide film, a silicon nitride film, and a silicon oxynitride film. However, embodiments of the present disclosure are not limited thereto. In FIG. 5 and FIG. 6, the cell element isolation film 105 is illustrated as being embodied as one insulating film (e.g., a single-layer film). However, this is intended only for convenience of illustration, and embodiments of the present disclosure are not limited thereto. Depending on a width of each of the cell element isolation film 105 and the cell area isolation film 22, each of the cell element isolation film 105 and the cell area isolation film 22 may be formed as one insulating film, or may be formed as a stack of a plurality of insulating films.

In FIG. 5 and FIG. 6, it is illustrated that an upper surface of the cell element isolation film 105 and an upper surface of the substrate 100 are coplanar with each other. However, this is intended only for convenience of illustration, and embodiments of the present disclosure are not limited thereto.

The cell gate structure 110 may be disposed in the substrate 100 and the cell element isolation film 105. The cell gate structure 110 may extend across the cell element isolation film 105 and the cell active area ACT defined by the cell element isolation film 105. The cell gate structure 110 may include a cell gate trench 115 formed in the substrate 100 and the cell element isolation film 105, a cell gate insulating film 111, a cell gate electrode 112, a cell gate capping pattern 113, and a cell gate capping conductive film 114. In this regard, the cell gate electrode 112 may correspond to the word-line WL. Unlike what is illustrated, the cell gate structure 110 may not include the cell gate capping conductive film 114.

The cell gate trench 115 may be relatively deep within the cell element isolation film 105 and may be relatively shallow within the cell active areas ACT. A bottom surface of the cell gate electrode 112 may be curved. That is, the depth of the cell gate trench 115 in the cell element isolation film 105 may be greater than the depth of the cell gate trench 115 in the cell active area ACT.

The cell gate insulating film 111 may extend along a sidewall and a bottom face of the cell gate trench 115. The cell gate insulating film 111 may extend along a profile of at least a portion of the cell gate trench 115. The cell gate insulating film 111 may be formed of or include, for example, at least one of silicon oxide, silicon nitride, silicon oxynitride, or a high dielectric constant material having a higher dielectric constant than that of silicon oxide. The high dielectric constant material may include, for example, at least one of hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, lead zinc niobate, or combinations thereof. However, embodiments of the present disclosure are not limited thereto.

The cell gate electrode 112 may be formed on the cell gate insulating film 111. The cell gate electrode 112 may fill a portion of the cell gate trench 115. The cell gate capping conductive film 114 may extend along an upper surface of the cell gate electrode 112. In FIG. 7, it is illustrated that the cell gate capping conductive film 114 does not cover a portion of the upper surface of the cell gate electrode 112. However, embodiments of the present disclosure are not limited thereto.

The cell gate electrode 112 may be formed of or include at least one of a metal, a conductive metal nitride, a conductive metal carbonitride, a conductive metal carbide, a metal silicide, a doped semiconductor material, a conductive metal oxynitride, or a conductive metal oxide. The cell gate electrode 112 may include, for example, at least one of TiN, TaC, TaN, TiSiN, TaSiN, TaTiN, TiAlN, TaAlN, WN, Ru, TiAl, TiAlC—N, TiAlC, TiC, TaCN, W, Al, Cu, Co, Ti, Ta, Ni, Pt, Ni—Pt, Nb, NbN, NbC, Mo, MoN, MOC, WC, Rh, Pd, Ir, Ag, Au, Zn, V, RuTiN, TiSi, TaSi, NiSi, CoSi, IrOₓ, RuOₓ, or combinations thereof. However, embodiments of the present disclosure are not limited thereto. The cell gate capping conductive film 114 may be formed of or include, for example, polysilicon or polysilicon germanium. However, embodiments of the present disclosure are not limited thereto.

The cell gate capping pattern 113 may be disposed on the cell gate electrode 112 and the cell gate capping conductive film 114. The cell gate capping pattern 113 may fill a portion of the cell gate trench 115 remaining after the cell gate electrode 112 and the cell gate capping conductive film 114 have been formed in the cell gate trench 115. Although the cell gate insulating film 111 is illustrated as extending along a sidewall of the cell gate capping pattern 113, embodiments of the present disclosure are not limited thereto. The cell gate capping pattern 113 may be formed of or include, for example, at least one of silicon nitride (SiN), silicon oxynitride (SiON), silicon oxide (SiO₂), silicon carbonitride (SiCN), silicon oxycarbonitride (SiOCN), or combinations thereof.

Although not shown, an impurity doped area may be formed on at least one side of the cell gate structure 110. The impurity doped area may be a source/drain area of a transistor.

The bit-line structure 140ST may include a cell conductive line 140 and a cell line capping film 144. The cell conductive line 140 may be disposed on a portion of each of the substrate 100 and the cell element isolation film 105 on which the cell gate structure 110 has been disposed.

The cell conductive line 140 may extend in the second direction D2. The cell conductive line 140 may intersect the cell element isolation film 105 and the cell active area ACT defined by the cell element isolation film 105. The cell conductive line 140 may be formed to intersect the cell gate structure 110. In this regard, the cell conductive line 140 may correspond to the bit-line BL.

The cell conductive line 140 may be embodied as a stack of multiple films. The cell conductive line 140 may include, for example, a first cell conductive film 141, a second cell conductive film 142, and a third cell conductive film 143. The first to third cell conductive films 141, 142, and 143 may be sequentially stacked on the substrate 100 and the cell element isolation film 105. Although the cell conductive line 140 is illustrated as being embodied as the stack of three films, embodiments of the present disclosure are not limited thereto.

Each of the first to third cell conductive films 141, 142, and 143 may be formed of or include, for example, at least one of semiconductor material doped with impurities, conductive silicide compound, conductive metal nitride, two-dimensional (2D) material, and metal. In the semiconductor memory device according to some embodiments, the two-dimensional material may be a metallic material and/or a semiconductor material. The two-dimensional material (2D material) may include a two-dimensional allotrope or a two-dimensional compound. For example, the 2D material may include at least one of graphene, molybdenum disulfide (MoS₂), molybdenum diselenide (MoSe₂), tungsten diselenide (WSe₂), and tungsten disulfide (WS₂). However, the present disclosure is not limited thereto. In other words, the above-described two-dimensional materials are listed only by way of example. The two-dimensional material that may be included in the semiconductor memory device of the present disclosure is not limited to the above-described materials.

For example, the first cell conductive film 141 may include a doped semiconductor material, the second cell conductive film 142 may include at least one of a conductive silicide compound, a conductive metal nitride, and a two-dimensional material, and the third cell conductive film 143 may include metal. However, embodiments of the present disclosure are not limited thereto.

The bit-line contact 146 may be disposed between the cell conductive line 140 and the substrate 100. That is, the cell conductive line 140 may be formed on the bit-line contact 146. For example, the bit-line contact 146 may be disposed at a point where the cell conductive line 140 intersects the middle portion of the cell active area ACT having the elongate island shape. The bit-line contact 146 may be formed between the bit-line connection area 103a and the cell conductive line 140 in a vertical direction (e.g., a thickness direction of the substrate 100).

The bit-line contact 146 may electrically connect the cell conductive line 140 and the substrate 100 to each other. In this regard, the bit-line contact 146 may correspond to the direct contact DC. The bit-line contact 146 may be formed of or include, for example, at least one of a semiconductor material doped with impurities, a conductive silicide compound, a conductive metal nitride, or a metal.

In FIG. 5, in an area overlapping an upper surface of the bit-line contact 146, the cell conductive line 140 may include the second cell conductive film 142 and the third cell conductive film 143. In an area that does not overlap with the upper surface of the bit-line contact 146, the cell conductive line 140 may include the first to third cell conductive films 141, 142, and 143. A thickness of a portion of the cell conductive line 140 in the area overlapping with the upper surface of the bit-line contact 146 may be different from a thickness of a portion of the cell conductive line 140 in the area non-overlapping with the upper surface of the bit-line contact 146.

The cell line capping film 144 may be disposed on the cell conductive line 140. The cell line capping film 144 may extend in the second direction D2 and along an upper surface of the cell conductive line 140. In this regard, the cell line capping film 144 may be formed of or include, for example, at least one of silicon nitride, silicon oxynitride, silicon carbonitride, or silicon oxycarbonitride. In the semiconductor memory device according to some embodiments, the cell line capping film 144 may include, for example, a silicon nitride film. Although the cell line capping film 144 is illustrated as being embodied as a single film, embodiments of the present disclosure are not limited thereto. In other words, the cell line capping film 144 may be embodied as a stack of multi-films. However, when the films constituting the stack are made of the same material, the cell line capping film 144 may be considered as a single film.

The cell insulating film 130 may be disposed on the substrate 100 and the cell element isolation film 105. More specifically, the cell insulating film 130 may be formed on a portion of each of the substrate 100 and the cell element isolation film 105 on which the bit-line contact 146 is not disposed. The cell insulating film 130 may be disposed between the substrate 100 and the cell conductive line 140 and between the cell element isolation film 105 and the cell conductive line 140 as shown, e.g., in FIG. 5.

It is illustrated that the cell insulating film 130 may be embodied as a stack of a first cell insulating film 131 and a second cell insulating film 132. However, the cell insulating film 130 may be embodied as a single film. For example, the first cell insulating film 131 may include a silicon oxide film, while the second cell insulating film 132 may include a silicon nitride film. However, embodiments of the present disclosure are not limited thereto. In another example, unlike what is shown, the cell insulating film 130 may include three or more insulating films. When the cell insulating film 130 includes a third cell insulating film, the third cell insulating film may be a silicon oxide film.

In the cross-sectional view of FIG. 5, the upper surface 100US of the substrate may be defined at a boundary between the cell insulating film 130 and the substrate 100.

A cell line spacer 150 may be disposed on a sidewall of each of the cell conductive line 140 and the cell line capping film 144. The cell line spacer 150 may be formed on the substrate 100 and the cell element isolation film 105 in an area around an area in which the cell conductive line 140 is disposed on the bit-line contact 146. The cell line spacer 150 may be disposed on a sidewall of each of the cell conductive line 140, the cell line capping film 144, and the bit-line contact 146.

In an area around an area in which the cell conductive line 140 is formed and the bit-line contact 146 is absent, the cell line spacer 150 may be disposed on the cell insulating film 130. The cell line spacer 150 may be disposed on a sidewall of each of the cell conductive line 140 and the cell line capping film 144.

The cell line spacer 150 may be disposed on a major sidewall extending in the second direction D2 in an elongate manner among the sidewalls of the bit-line structure 140ST.

The cell line spacer 150 is illustrated as a stack of multiple films including first to fourth cell line spacers 151, 152, 153, and 154. However, the cell line spacer 150 may be embodied as a single film. For example, each of the first to fourth cell line spacers 151, 152, 153, and 154 may be formed of or include one of a silicon oxide film, a silicon nitride film, a silicon oxynitride film (SiON), a silicon oxycarbonitride film (SiOCN), air, or a combination thereof. However, embodiments of the present disclosure are not limited thereto. For example, the second cell line spacer 152 may not be disposed on the cell insulating film 130, but may be disposed on a sidewall of the bit-line contact 146.

A fence pattern 170 may be disposed on the substrate 100 and the cell element isolation film 105. The fence pattern 170 may be formed to overlap the cell gate structure 110 formed in the substrate 100 and the cell element isolation film 105. The fence pattern 170 may be disposed between the bit-line structures 140ST extending in the second direction D2. The fence pattern 170 may be formed of or include, for example, at least one of silicon oxide, silicon nitride, silicon oxynitride, or combinations thereof.

The plurality of storage contacts 120 may be disposed between cell conductive lines 140 adjacent to each other in the first direction D1. The storage contact 120 may be disposed between fence patterns 170 adjacent to each other in the second direction D2 (see, e.g., FIG. 6). The storage contact 120 may overlap a portion of each of the substrate 100 and the cell element isolation film 105 disposed between adjacent cell conductive lines 140. The storage contact 120 may be connected to the storage connection area 103b of the cell active area ACT. In this regard, the storage contact 120 may correspond to the buried contact BC.

The storage contact 120 may be formed of or include, for example, at least one of a semiconductor material doped with impurities, a conductive silicide compound, a conductive metal nitride, or a metal.

The plurality of storage pads 160 may be disposed on the storage contact 120. The storage pad 160 may be electrically connected to the storage contact 120. In this regard, the storage pad 160 may correspond to the landing pad LP.

The storage pad 160 may overlap a portion of an upper surface of the bit-line structure 140ST. For example, the storage pad 160 may overlap an upper surface 144US of the cell line capping film in a thickness direction of the substrate 100.

The storage pad 160 may include a storage pad barrier film 161 and a storage pad plug film 162. The storage pad barrier film 161 may be disposed between the storage contact 120 and the storage pad plug film 162. The storage pad barrier film 161 may be connected to the storage contact 120. A portion of the storage pad barrier film 161 may extend along the upper surface 144US of the cell line capping film.

The storage pad plug film 162 includes an upper surface 160US of the storage pad 160. The upper surface 160US of the storage pad 160 may be an upper surface of the storage pad plug film 162.

Each of the storage pad barrier film 161 and the storage pad plug film 162 may be formed of or include a conductive material. The storage pad barrier film 161 may include, for example, at least one of a conductive silicide compound, a conductive metal nitride, a conductive metal carbide, a conductive metal oxide, and a conductive metal carbonitride. The storage pad plug film 162 may include a metal. For example, the storage pad plug film 162 may be made of the metal.

A plurality of storage pad capping films 275 may be disposed on the storage pad 160. The storage pad capping film 275 may be disposed on each storage pad 160.

The storage pad capping film 275 may contact the upper surface 160US of the storage pad 160. The storage pad capping film 275 may be in contact with the storage pad plug film 162. It will be understood that when an element is referred to as “contacting” or “in contact with” another element (or using any form of the word “contact”), there are no intervening elements present at the point of contact.

The storage pad capping film 275 may include an upper surface 275US and a bottom surface 275BS opposite to each other. The bottom surface 275BS of the storage pad capping film 275 may face the storage pad 160. The bottom surface 275BS of the storage pad capping film 275 may contact the upper surface 160US of the storage pad.

In a semiconductor memory device according to some embodiments, the storage pad capping film 275 may be a first storage pad capping film 276. The first storage pad capping film 276 may be formed of or include metal nitride.

In one example, the first storage pad capping film 276 may include nitride of the metal included in the storage pad plug film 162. For example, when the storage pad plug film 162 is made of tungsten (W), the first storage pad capping film 276 may include tungsten nitride (WN).

In another example, the first storage pad capping film 276 may include a nitride of a metal other than the metal included in the storage pad plug film 162. Hereinafter, an example in which the first storage pad capping film 276 includes the nitride of the metal included in storage pad plug film 162 is described.

A pad isolation pattern 180 may be formed on the storage pad 160 and the bit-line structure 140ST. For example, the pad isolation pattern 180 may be disposed on the cell line capping film 144.

The pad isolation pattern 180 may define an area of the storage pad 160 as each of a plurality of isolated areas. The pad isolation pattern 180 may isolate adjacent storage pads 160 from each other. The pad isolation pattern 180 may isolate adjacent storage pad capping films 275 from each other.

The pad isolation pattern 180 does not cover the upper surface 160US of the storage pad. The pad isolation pattern 180 does not cover the upper surface 275US of the storage pad capping film 275.

The pad isolation pattern 180 may be formed of or include an insulating material. The pad isolation pattern 180 may electrically insulate adjacent ones of the plurality of storage pads 160 from each other. For example, the pad isolation pattern 180 may include at least one of a silicon oxide film, a silicon nitride film, a silicon oxynitride film, a silicon oxycarbonitride film, and a silicon carbonitride film.

As shown, e.g., in FIG. 5, a height H41 from the upper surface 100US of the substrate 100 to the upper surface 160US of the storage pad 160 is smaller than a height H42 from the upper surface 100US of the substrate 100 to an upper surface 180US of the pad isolation pattern 180. In a semiconductor memory device according to some embodiments, a height H43 from the upper surface 100US of the substrate 100 to the upper surface 275US of the storage pad capping film 275 may be equal to the height H42 from the upper surface 100US of the substrate 100 to the upper surface 180US of the pad isolation pattern 180. The upper surface 180US of the pad isolation pattern 180 and the upper surface 275US of the storage pad capping film 275 may be coplanar with each other. However, embodiments of the present disclosure are not limited thereto.

An upper etch stop film 292 may be disposed on the pad isolation pattern 180 and the storage pad 160. The upper etch stop film 292 may be disposed on the storage pad capping film 275. The upper etch stop film 292 may extend not only to the cell area 20 but also to the peripheral area 24. The upper etch stop film 292 may be formed of or include at least one of a silicon nitride film, a silicon carbonitride film, a silicon boron nitride (SiBN) film, a silicon oxynitride film, and a silicon oxycarbide film. However, embodiments of the present disclosure are not limited thereto.

The data storage pattern 190 may be disposed on the storage pad 160. The data storage pattern 190 may be electrically connected to the storage pad 160. The storage pad capping film 275 may be disposed between the storage pad 160 and the data storage pattern 190. The data storage pattern 190 may be in contact with the storage pad capping film 275.

A portion of the data storage pattern 190 may be disposed within the upper etch stop film 292. The data storage pattern 190 may include, for example, a capacitor. However, embodiments of the present disclosure are not limited thereto. The data storage pattern 190 includes the first lower electrode 191, a first capacitor dielectric film 192, and the first upper electrode 193.

The first lower electrode 191 may be disposed on the storage pad 160. The first lower electrode 191 may be in contact with the storage pad capping film 275. The first lower electrode 191 is shown as having a pillar shape. However, embodiments of the present disclosure are not limited thereto. In another example, the first lower electrode 191 may have a cylindrical shape.

The first capacitor dielectric film 192 is disposed on the first lower electrode 191. The first capacitor dielectric film 192 may be formed along a profile of the first lower electrode 191. The first upper electrode 193 is disposed on the first capacitor dielectric film 192. The first upper electrode 193 may surround an outer sidewall of the first lower electrode 191.

For example, the first capacitor dielectric film 192 may be disposed so as to vertically overlap the first upper electrode 193. The first capacitor dielectric film 192 may not extend to the peripheral area 24.

Each of the first lower electrode 191 and the first upper electrode 193 may be formed of or include, for example, a doped semiconductor material, a conductive metal nitride such as titanium nitride, tantalum nitride, niobium nitride or tungsten nitride, etc., a metal such as ruthenium, iridium, titanium, or tantalum, etc., or a conductive metal oxide such as iridium oxide or niobium oxide, etc. However, embodiments of the present disclosure are not limited thereto.

For example, the first capacitor dielectric film 192 may be formed of or include at least one of a ferroelectric material, an antiferroelectric material, and a paraelectric material. For example, the first capacitor dielectric film 192 may include at least one of a ferroelectric material, an antiferroelectric material, a paraelectric material, a combination of a ferroelectric material and an antiferroelectric material, a combination of a ferroelectric material and a paraelectric material, a combination of a paraelectric material and an antiferroelectric material, or a combination of a ferroelectric material, an antiferroelectric material, and a paragenetic material.

In one example, the first capacitor dielectric film 192 may include a stacked film structure in which a zirconium oxide film, an aluminum oxide film, and a zirconium oxide film are sequentially stacked. In another example, the first capacitor dielectric film 192 may include a dielectric film including hafnium (Hf). The suggestion regarding the material of the first capacitor dielectric film 192 as described above is merely an example, and the technical idea of the present disclosure is not limited thereto.

Unlike what is described above, the data storage pattern 190 may be a variable resistance pattern that may be switched to between two resistance states under an electrical pulse applied to a memory element. For example, the data storage pattern 190 may include a phase-change material whose crystal state changes depending on an amount of current, perovskite compounds, transition metal oxides, magnetic materials, ferromagnetic materials, or antiferromagnetic materials.

A peripheral element isolation film 26 may be formed within the substrate 100 and in the peripheral area 24. The peripheral element isolation film 26 may define a peripheral active area in the peripheral area 24. An upper surface of the peripheral element isolation film 26 is shown as being coplanar with the upper surface 100US of the substrate 100. However, embodiments of the present disclosure are not limited thereto. The peripheral element isolation film 26 may be formed of or include, but is not limited to, at least one of, for example, a silicon oxide film, a silicon nitride film, and a silicon oxynitride film.

The peripheral gate structure 240ST may be disposed on the substrate 100 and in peripheral area 24. The peripheral gate structure 240ST may be disposed on a peripheral active area defined by the peripheral element isolation film 26.

The peripheral gate structure 240ST may include a peripheral gate insulating film 230, a peripheral gate conductive film 240, and a peripheral capping film 244 sequentially stacked on the substrate 100. The peripheral gate structure 240ST may include a peripheral spacer 245 disposed on a sidewall of the peripheral gate conductive film 240 and a sidewall of the peripheral capping film 244.

The peripheral gate conductive film 240 may include first to third peripheral conductive films 241, 242, and 243 sequentially stacked on the peripheral gate insulating film 230. For example, an additional conductive film may not be disposed between the peripheral gate conductive film 240 and the peripheral gate insulating film 230. In another example, unlike what is shown, an additional conductive film, such as a work function conductive film, may be disposed between the peripheral gate conductive film 240 and the peripheral gate insulating film 230.

Although two peripheral gate structures 240ST are shown as being disposed between adjacent peripheral element isolation films 26, this is only for convenience of illustration and embodiments of the present disclosure are not limited thereto.

For example, the peripheral gate conductive film 240 may have the same stacked structure as that of the cell conductive line 140. A thickness T21 of the peripheral gate conductive film 240 may be equal to a thickness T11 of the cell conductive line 140.

The first peripheral conductive film 241 may include the same material as that of the first cell conductive film 141. The second peripheral conductive film 242 may include the same material as that of the second cell conductive film 142. The third peripheral conductive film 243 may include the same material as that of the third cell conductive film 143.

The peripheral gate insulating film 230 may be formed of or include, for example, silicon oxide, silicon nitride, silicon oxynitride, or a high dielectric constant material having a higher dielectric constant than that of silicon oxide.

For example, the peripheral spacer 245 may be formed of or include at least one of silicon nitride, silicon oxynitride, silicon oxide, silicon carbonitride, silicon oxycarbonitride, and combinations thereof. Although the peripheral spacer 245 is shown as being formed as a single film, this is only for convenience of illustration and embodiments of the present disclosure are not limited thereto. In another example, the peripheral spacer 245 may be embodied as a stack of multi-films.

For example, the peripheral capping film 244 may be formed of or include at least one of a silicon nitride film, silicon oxynitride, and silicon oxide. For example, a thickness T22 of peripheral capping film 244 is smaller than a thickness T12 of the cell line capping film 144. Furthermore, a vertical level of the upper surface 244US of the peripheral capping film 244 is lower than that of the upper surface 144US of the cell line capping film 144. For example, the thickness T12 of the cell line capping film 144 may be a thickness of the cell line capping film 144 on the cell conductive line 140 as shown in FIG. 5.

A lower etch stop film 250 may be disposed on the substrate 100. The lower etch stop film 250 may be formed along a profile of the peripheral gate structure 240ST. For example, the lower etch stop film 250 may be formed of or include at least one of silicon nitride, silicon oxynitride, silicon carbonitride, and silicon oxycarbonitride.

A first peripheral interlayer insulating film 290 may be disposed on the lower etch stop film 250. The first peripheral interlayer insulating film 290 may be disposed around the peripheral gate structure 240ST. For example, the first peripheral interlayer insulating film 290 may be formed of or include a silicon oxide-based insulating material. The first peripheral interlayer insulating film 290 may include, but is not limited to, silicon oxide.

A vertical level of the upper surface 290US of the first peripheral interlayer insulating film 290 may be lower than a vertical level of the upper surface 244US of the peripheral capping film 244. For example, a height HI from the upper surface 100US of the substrate 100 to an upper surface 290US of the first peripheral interlayer insulating film 290 may be smaller than a height H21 from the upper surface 100US of the substrate 100 to an upper surface 244US of the peripheral capping film 244.

The height H1 from the upper surface 100US of the substrate 100 to the upper surface 290US of the first peripheral interlayer insulating film 290 may be measured at a position near a center between adjacent peripheral gate structures 240ST. The height H21 from the upper surface 100US of the substrate 100 to the upper surface 244US of the peripheral capping film 244 may be measured at a position near a center of a width of the peripheral capping film 244.

The height H1 from the upper surface 100US of the substrate 100 to the upper surface 290US of the first peripheral interlayer insulating film 290 may be smaller than a height H22 from the upper surface 100US of the substrate 100 to a top level of the peripheral spacer 245.

For example, the height H21 from the upper surface 100US of the substrate 100 to the upper surface 244US of the peripheral capping film 244 may be equal to the height H22 from the upper surface 100US of the substrate 100 to the top level of the peripheral spacer 245.

Unlike what is shown, in another example, a vertical level of the upper surface of the peripheral spacer 245 may be lower than a vertical level of the upper surface 244US of the peripheral capping film 244 due to an etching process during the manufacturing process. In this case, the height H21 from the upper surface 100US of the substrate 100 to the upper surface 244US of the peripheral capping film 244 may be greater than or equal to the height H22 from the upper surface 100US of the substrate 100 to the top level of the peripheral spacer 245.

An inserted interlayer insulating film 291 is disposed on the peripheral gate structure 240ST and the first peripheral interlayer insulating film 290. The inserted interlayer insulating film 291 may cover the peripheral gate structure 240ST and the first peripheral interlayer insulating film 290. The inserted interlayer insulating film 291 may cover a portion of the lower etch stop film 250 that protrudes upwardly beyond the upper surface 290US of the first peripheral interlayer insulating film 290.

The upper surface 290US of the first peripheral interlayer insulating film 290 is shown as being flat. However, embodiments of the present disclosure are not limited thereto. The upper surface 290US of the first peripheral interlayer insulating film 290 may be a curved surface convex toward substrate 100.

The inserted interlayer insulating film 291 may include a material different from that of the first peripheral interlayer insulating film 290. The inserted interlayer insulating film 291 may be formed of or include, for example, a silicon nitride-based insulating material. For example, the inserted interlayer insulating film 291 may include silicon nitride.

A portion of the inserted interlayer insulating film 291 extends downwardly into a space between adjacent peripheral gate structures 240ST. In other words, a vertical level of the bottom surface of the inserted interlayer insulating film 291 may be lower than a vertical level of the upper surface 244US of the peripheral capping film 244.

Thus, the inserted interlayer insulating film 291 may protect the first peripheral interlayer insulating film 290 in an etching process included in a process of manufacturing the data storage pattern 190. In the etching process included in the process of manufacturing the data storage pattern 190, the inserted interlayer insulating film 291 may prevent defects caused by etching the first peripheral interlayer insulating film 290.

Peripheral contact plugs 260 may be respectively disposed on both opposing sides of the peripheral gate structure 240ST. The peripheral contact plug 260 may extend through the inserted interlayer insulating film 291 and the first peripheral interlayer insulating film 290 to a portion of the substrate 100 in the peripheral area 24.

The peripheral contact plug 260 may include a peripheral plug barrier film 261 and a peripheral plug filling film 262. The peripheral plug filling film 262 may be disposed on the peripheral plug barrier film 261.

The peripheral wiring lines 265 may be disposed on the inserted interlayer insulating film 291. The peripheral wiring line 265 may be disposed on the peripheral gate structure 240ST. The peripheral wiring line 265 may be connected to the peripheral contact plug 260. In the cross-sectional view, at positions where the peripheral wiring line 265 is connected to the peripheral contact plug 260, the peripheral wiring line 265 may be a portion disposed on the upper surface 291US of the inserted interlayer insulating film 291. The peripheral wiring line 265 may be disposed on the upper surface 291US of the inserted interlayer insulating film.

The peripheral wiring line 265 may include a peripheral wiring barrier film 266 and a peripheral wiring extension line 267. The peripheral wiring extension line 267 may be disposed on the peripheral wiring barrier film 266.

The peripheral wiring extension line 267 includes an upper surface 265US of the peripheral wiring line 265. The upper surface 267US of the peripheral wiring extension line 267 may be an upper surface 265US of the peripheral wiring line 265.

The peripheral wiring line 265 includes a sidewall 265SW. The sidewall 265SW of the peripheral wiring line 265 may be defined by the peripheral wiring barrier film 266 and the peripheral wiring extension line 267.

In a semiconductor memory device according to some embodiments, the peripheral wiring extension line 267 may be directly connected to the peripheral plug filling film 262. The peripheral wiring barrier film 266 may be directly connected to the peripheral plug barrier film 261. The peripheral contact plug 260 and the peripheral wiring line 265 may be formed (e.g., integrally formed) in the same manufacturing process.

The peripheral wiring barrier film 266 may include the same material as that of the peripheral plug barrier film 261. The peripheral wiring barrier film 266 may be formed of or include, for example, at least one of a conductive silicide compound, a conductive metal nitride, a conductive metal carbide, a conductive metal oxide, and a conductive metal carbonitride. In a semiconductor memory device according to some embodiments, the peripheral wiring barrier film 266 may include the same material as that of the storage pad barrier film 161.

The peripheral wiring extension line 267 may include the same material as that of the peripheral plug filling film 262. The peripheral wiring extension line 267 may be formed of or include a metal. For example, the peripheral wiring extension line 267 may be made of a metal. The peripheral wiring extension line 267 may include the same metal as that of the storage pad plug film 162.

Unlike what is shown, the peripheral contact plug 260 may include a peripheral plug filling film 262 made of the metal but may be free of the peripheral plug barrier film 261. The peripheral wiring line 265 may include the peripheral wiring extension line 267 made of a metal but may be free of the peripheral wiring barrier film 266.

The peripheral wiring capping films 270 may be disposed on the peripheral wiring line 265. The peripheral wiring capping film 270 may be disposed on each peripheral wiring line 265.

The peripheral wiring capping film 270 may contact the upper surface 265US of the peripheral wiring line 265. The peripheral wiring capping film 270 may contact the peripheral wiring extension line 267.

The peripheral wiring capping film 270 may include an upper surface 270US and a bottom surface 270BS opposite to each other. The bottom surface 270BS of the peripheral wiring capping film may face the substrate 100. The bottom surface 270BS of the peripheral wiring capping film may contact the upper surface 267US of the peripheral wiring extension line 267. The peripheral wiring capping film 270 includes a sidewall 270SW connecting the bottom surface 270BS of the peripheral wiring capping film 270 and the upper surface 270US of the peripheral wiring capping film 270 to each other.

A width W12 of the bottom surface 270BS of the peripheral wiring capping film 270 is equal to a width W11 of the upper surface 267US of the peripheral wiring extension line 267 (see, e.g., FIG. 7). In the cross-sectional view of FIG. 4, at positions in which a plug pattern connected to the peripheral wiring line 265 is absent, the peripheral wiring capping film 270 may cover an entirety of the upper surface 267US of the peripheral wiring extension line 267. The sidewall 270SW of the peripheral wiring capping film 270 may be aligned with the sidewall 265SW of the peripheral wiring line 265.

The peripheral wiring capping film 270 does not extend along the sidewall 265SW of the peripheral wiring line 265. The peripheral wiring capping film 270 may not contact the sidewall 265SW of the peripheral wiring line 265.

In a semiconductor memory device according to some embodiments, the peripheral wiring capping film 270 may be the first peripheral wiring capping film 271. The first peripheral wiring capping film 271 may be formed of or include metal nitride.

In one example, the first peripheral wiring capping film 271 may include nitride of the metal included in the peripheral wiring extension line 267. Since the peripheral wiring extension line 267 may include the same metal as that of the storage pad plug film 162, the first peripheral wiring capping film 271 and the first storage pad capping film 276 may include the same metal nitride. When the peripheral wiring extension line 267 is made of tungsten (W), the first peripheral wiring capping film 271 may include tungsten nitride (WN).

In another example, the first peripheral wiring capping film 271 may include a nitride of a metal other than the metal included in the peripheral wiring extension line 267. Since the first peripheral wiring capping film 271 and the first storage pad capping film 276 are formed in the same process, the first peripheral wiring capping film 271 includes the same metal nitride as that of the first storage pad capping film 276.

Hereinafter, an example in which the first peripheral wiring capping film 271 includes the nitride of the metal included in the peripheral wiring extension line 267 is described.

The peripheral wiring isolation pattern 280 may isolate adjacent peripheral wiring lines 265 from each other. The peripheral wiring line 265 may include a first peripheral wiring line 265_1 and a second peripheral wiring line 265_2 adjacent to each other as shown, e.g., in FIGS. 7 and 8. In this case, the peripheral wiring isolation pattern 280 may isolate the first peripheral wiring line 265_1 and the second peripheral wiring line 265_2 from each other.

The peripheral wiring isolation pattern 280 may isolate adjacent peripheral wiring capping films 270 from each other. The peripheral wiring isolation pattern 280 may isolate a portion of the peripheral wiring capping film 270 in contact with the first peripheral wiring line 265_1 and a portion of the peripheral wiring capping film 270 in contact with the second peripheral wiring line 265_2 from each other.

The peripheral wiring isolation pattern 280 may contact the sidewall 265SW of the peripheral wiring line 265. The peripheral wiring isolation pattern 280 may be in contact with the sidewall 270SW of the peripheral wiring capping film 270.

The peripheral wiring capping film 270 may not extend along the upper surface 280US of the peripheral wiring isolation pattern 280. The peripheral wiring isolation pattern 280 does not cover the upper surface 270US of the peripheral wiring capping film 270.

The peripheral wiring isolation pattern 280 may be formed of or include an insulating material. The peripheral wiring isolation pattern 280 may electrically insulate adjacent peripheral wiring lines 265 from each other. For example, the peripheral wiring isolation pattern 280 may include at least one of a silicon oxide film, a silicon nitride film, a silicon oxynitride film, a silicon oxycarbonitride film, and a silicon carbonitride film.

A height H31 from the upper surface 100US of the substrate 100 to the upper surface 267US of the peripheral wiring extension line 267 is smaller than a height H32 from the upper surface 100US of the substrate 100 to the upper surface 280US of the peripheral wiring isolation pattern 280. In a semiconductor memory device according to some embodiments, a height H33 from the upper surface 100US of the substrate 100 to the upper surface 270US of the peripheral wiring capping film 270 may be equal to the height H32 from the upper surface 100US of the substrate 100 to the upper surface 280US of the peripheral wiring isolation pattern 280.

In FIG. 7, the upper surface 280US of the peripheral wiring isolation pattern 280 may be flat. The upper surface 280US of the peripheral wiring isolation pattern 280 may be coplanar with the upper surface 270US of the peripheral wiring capping film 270.

In FIG. 8, the upper surface 280US of the peripheral wiring isolation pattern 280 may not be flat. In the cross-sectional view, the upper surface 280US of the peripheral wiring isolation pattern 280 may have a shape similar to a “V” shape. For example, a vertical level of the upper surface 280US of the peripheral wiring isolation pattern 280 may generally decrease from edges of the peripheral wiring isolation pattern 280 toward a center thereof.

In FIG. 7 and FIG. 8, the upper surface 280US of the peripheral wiring isolation pattern 280 may include a closest point 280US_NP in contact with the peripheral wiring capping film 270. For example, the height H32 from the upper surface 100US of the substrate 100 to the upper surface 280US of the peripheral wiring isolation pattern 280 may be a height measured at the closest point 280US_NP of the upper surface 280US of the peripheral wiring isolation pattern 280.

After the peripheral wiring line 265 has been formed, a subsequent process using an etchant or process gas containing oxygen may proceed. The peripheral wiring extension line 267 may be oxidized by oxygen used in the subsequent processes, thereby producing metal oxide. An electrical resistance of the peripheral wiring line 265 may be increased due to the produced metal oxide.

In this regard, the peripheral wiring capping film 270 may be formed on the peripheral wiring line 265. Thus, the peripheral wiring capping film 270 may prevent the peripheral wiring extension line 267 from being oxidized in the subsequent process using oxygen. Thus, the performance and reliability of the semiconductor memory device may be improved.

The upper etch stop film 292 may be disposed on the peripheral wiring isolation pattern 280 and the peripheral wiring capping film 270. For example, the upper etch stop film 292 may extend along the upper surface 270US of the peripheral wiring capping film 270 and the upper surface 280US of the peripheral wiring isolation pattern 280.

The upper etch stop film 292 does not contact the sidewall 265SW of the peripheral wiring line 265. In a semiconductor memory device according to some embodiments, the upper etch stop film 292 may not contact the sidewall 270SW of the peripheral wiring capping film 270.

A second peripheral interlayer insulating film 293 may be disposed on the upper etch stop film 292. Although not shown, the second peripheral interlayer insulating film 293 may cover a sidewall of the first upper electrode 193. The second peripheral interlayer insulating film 293 may be formed of or include an insulating material.

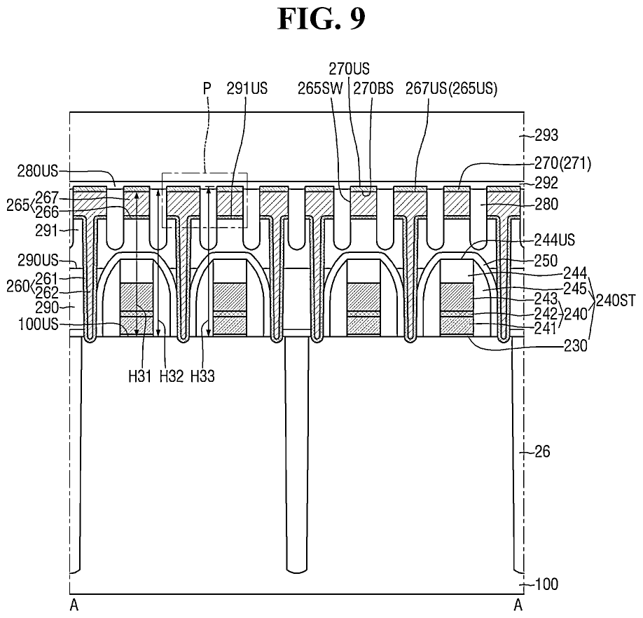

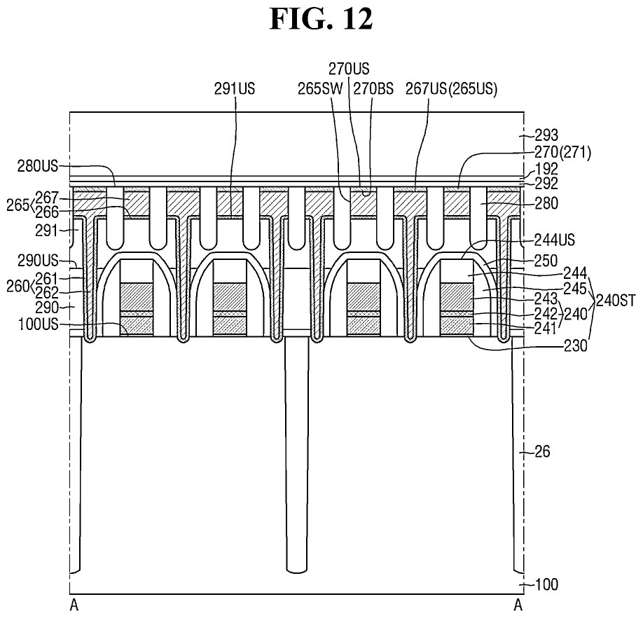

FIG. 9 to FIG. 11 are diagrams for illustrating a semiconductor memory device according to some embodiments. FIG. 12 is a diagram for illustrating a semiconductor memory device according to some embodiments. For convenience of description, differences thereof from what has been described above with reference to FIG. 1 to FIG. 8 will be mainly described below.

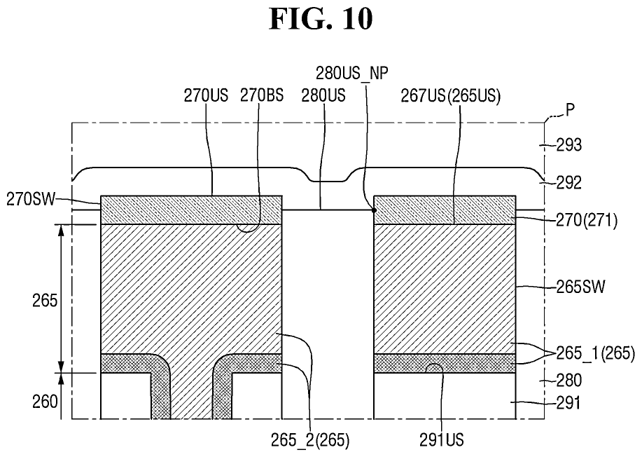

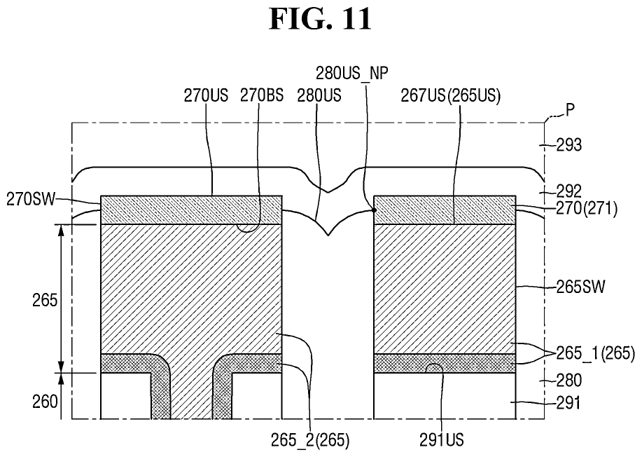

For reference, FIG. 9 and FIG. 12 are cross-sectional views cut along a line A-A of FIG. 1, respectively. FIG. 10 and FIG. 11 are respectively enlarged views of a P portion of FIG. 9.

Referring to FIG. 9 to FIG. 11, in the semiconductor memory device according to some embodiments, the height H32 from the upper surface 100US of the substrate 100 to the upper surface 280US of the peripheral wiring isolation pattern 280 may be smaller than the height H33 from the upper surface 100US of the substrate 100 to the upper surface 270US of the peripheral wiring capping film 270.

A vertical level of the upper surface 270US of the peripheral wiring capping film 270 may be higher than a vertical level of the upper surface 280US of the peripheral wiring isolation pattern 280. Thus, the upper etch stop film 292 may contact the sidewall 270SW of the peripheral wiring capping film 270. The upper etch stop film 292 may cover a portion of the sidewall 270SW of the peripheral wiring capping film 270.

Although not shown, a height H43 from the upper surface 100US of the substrate 100 to the upper surface (275US in FIG. 5) of the storage pad capping film 275 may be larger than a height H42 from the upper surface 100US of the substrate 100 to the upper surface 180US of the pad isolation pattern 180.

In FIG. 10, the upper surface 280US of the peripheral wiring isolation pattern 280 may be flat. In FIG. 11, the upper surface 280US of the peripheral wiring isolation pattern 280 may have a shape similar to a “V” shape.

Referring to FIG. 12, in the semiconductor memory device according to some embodiments, the first capacitor dielectric film 192 may be disposed between the upper etch stop film 292 and the second peripheral interlayer insulating film 293.

The first capacitor dielectric film 192 may extend along a boundary between the upper etch stop film 292 and the second peripheral interlayer insulating film 293. In other words, the first capacitor dielectric film 192 may be also disposed on the peripheral area (24 in FIG. 1).

The first capacitor dielectric film 192 may extend along the upper surface 270US of the peripheral wiring capping film 270 and the upper surface 280US of the peripheral wiring isolation pattern 280. The upper etch stop film 292 may be between the first capacitor dielectric film 192 and the peripheral wiring capping film 270, and may be between the first capacitor dielectric film 192 and the peripheral wiring isolation pattern 280.

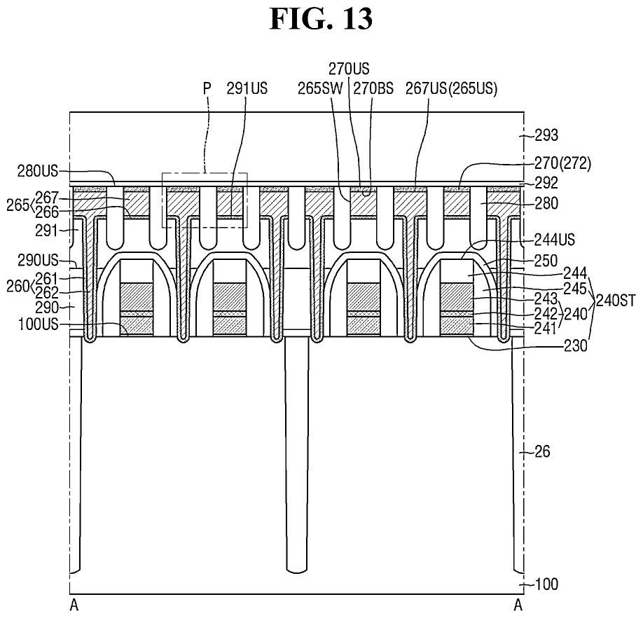

FIG. 13 to FIG. 16 are diagrams for illustrating a semiconductor memory device according to some embodiments. For convenience of description, differences thereof from what has been described above with reference to FIG. 1 to FIG. 8 will be mainly described below.

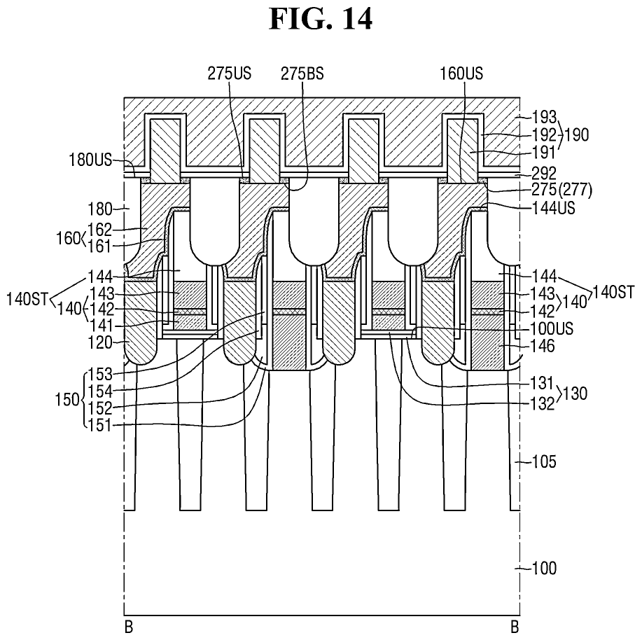

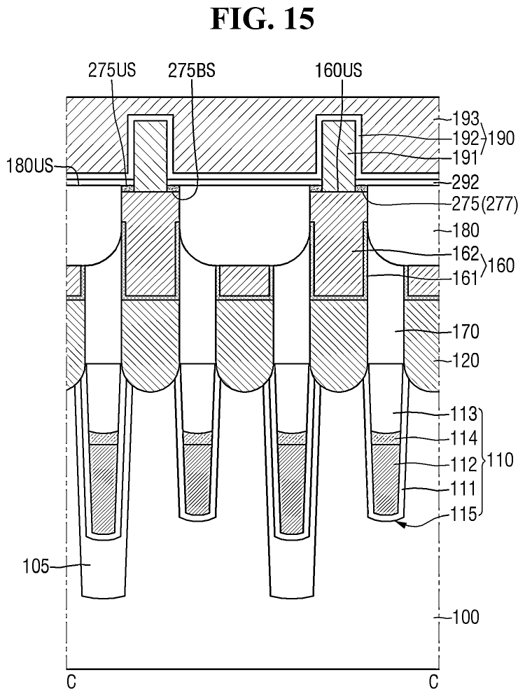

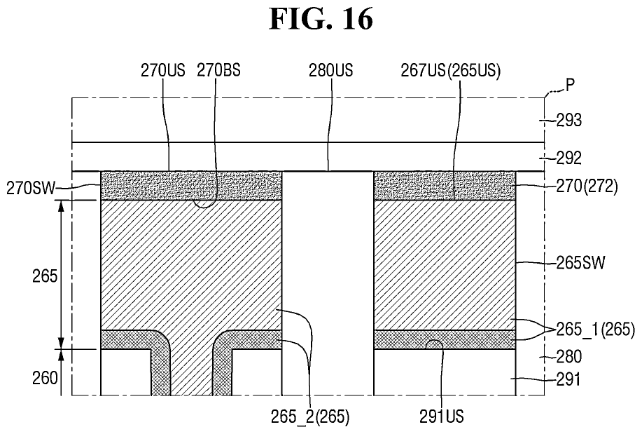

For reference, FIG. 13 is a cross-sectional view cut along a line A-A in FIG. 1. FIG. 14 and FIG. 15 are cross-sectional views taken along lines B-B and C-C of FIG. 2, respectively. FIG. 16 is an enlarged view of a P portion of FIG. 13.

Referring to FIG. 13 to FIG. 16, in the semiconductor memory device according to some embodiments, the peripheral wiring capping film 270 may be a second peripheral wiring capping film 272.

The second peripheral wiring capping film 272 may be formed of or include a silicon nitride-based insulating material. The silicon nitride-based insulating material may be silicon nitride, or an insulating material in which another material is contained in the silicon nitride. For example, the second peripheral wiring capping film 272 may include at least one of silicon nitride (SiN), silicon carbonitride (SiCN), and silicon boron nitride (SiBN). However, embodiments of the present disclosure are not limited thereto.

In FIG. 16, the upper surface 280US of the peripheral wiring isolation pattern 280 is shown as being flat. However, embodiments of the present disclosure are not limited thereto. In another example, the upper surface 280US of the peripheral wiring isolation pattern 280 may have the same shape as shown in FIG. 8.

The storage pad capping film 275 may be a second storage pad capping film 277. The second storage pad capping film 277 may be formed of or include a silicon nitride-based insulating material. The second storage pad capping film 277 includes the same insulating material as that of the second peripheral wiring capping film 272.

The first lower electrode 191 may contact the upper surface 160US of the storage pad 160. The first lower electrode 191 may be in contact with the storage pad plug film 162.

Unlike what is shown, a width of the first lower electrode 191 may be larger than a width of the storage pad capping film 275. In this case, in the cross-sectional view, the storage pad capping film 275 may not be visible along the line B-B and/or the line C-C.

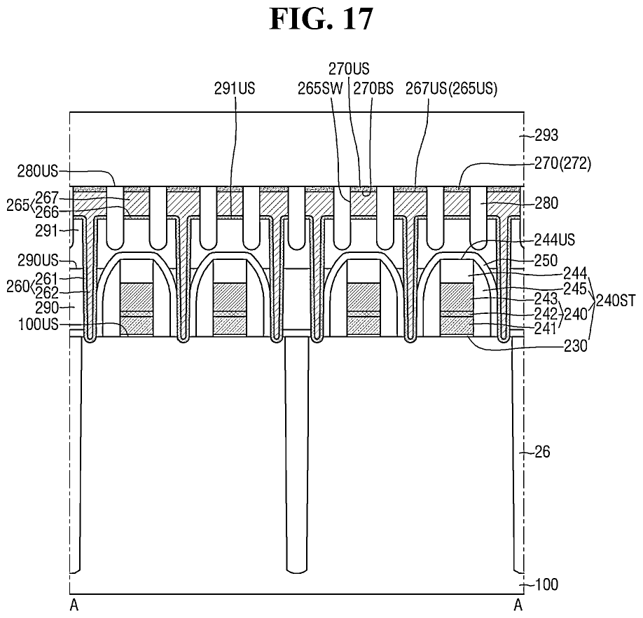

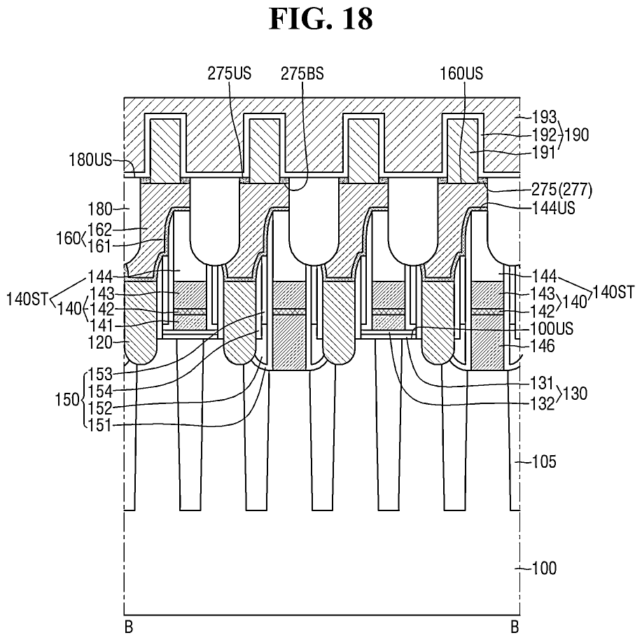

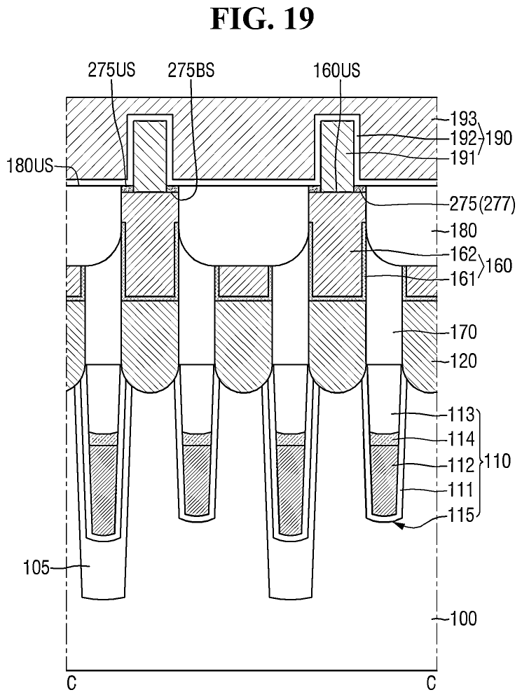

FIG. 17 to FIG. 19 are diagrams for illustrating a semiconductor memory device according to some embodiments. For convenience of description, differences thereof from what has been described above with reference to FIG. 13 to FIG. 16 will be mainly described below.

Referring to FIG. 17 to FIG. 19, in the semiconductor memory device according to some embodiments, the upper etch stop film (292 in FIG. 4) is not disposed between the second peripheral interlayer insulating film 293 and the second peripheral wiring capping film 272, and between the second peripheral interlayer insulating film 293 and the peripheral wiring isolation pattern 280.

For example, the second peripheral interlayer insulating film 293 may contact the upper surface 270US of the peripheral wiring capping film 270 and the upper surface 280US of the peripheral wiring isolation pattern 280.

The upper etch stop film (292 in FIG. 5 and FIG. 6) may not be disposed on the pad isolation pattern 180. For example, the first capacitor dielectric film 192 may contact the upper surface 180US of the pad isolation pattern 180.

Since each of the second peripheral wiring capping film 272 and the second storage pad capping film 277 include the insulating material, each of the second peripheral wiring capping film 272 and the second storage pad capping film 277 may serve as an etch stop film.

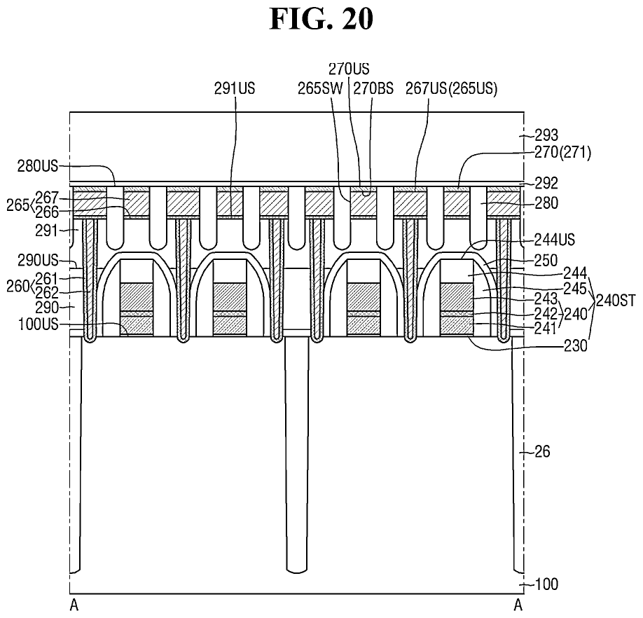

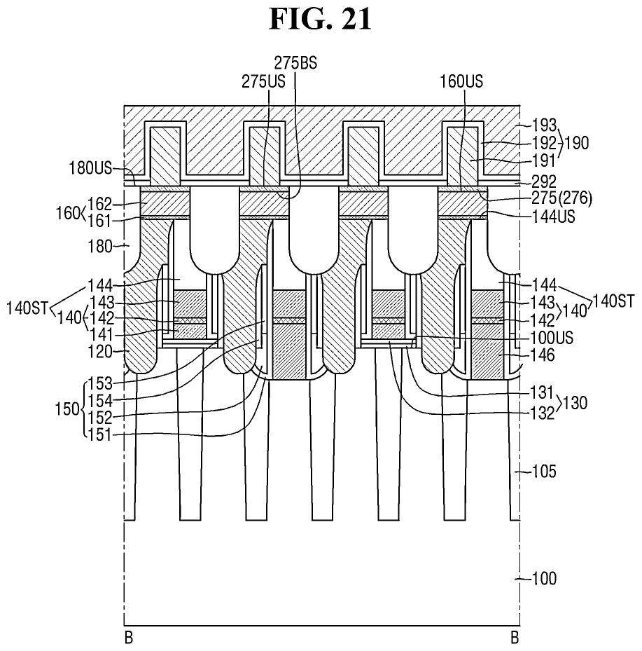

FIG. 20 and FIG. 21 are diagrams for illustrating a semiconductor memory device according to some embodiments. For convenience of description, differences thereof from what has been described above with reference to FIG. 1 to FIG. 8 will be mainly described below.

Referring to FIG. 20 and FIG. 21, in the semiconductor memory device according to some embodiments, the peripheral wiring extension line 267 is not directly connected to the peripheral plug filling film 262.

The peripheral wiring barrier film 266 may be disposed between the peripheral wiring extension line 267 and the peripheral plug filling film 262. For example, after the peripheral contact plug 260 has been formed, the peripheral wiring line 265 may be formed.

The upper surface of the storage contact 120 may be coplanar with the upper surface 144US of the cell line capping film 144.

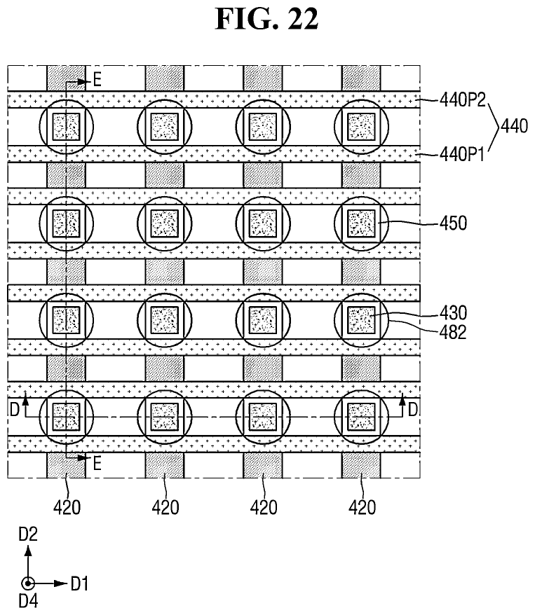

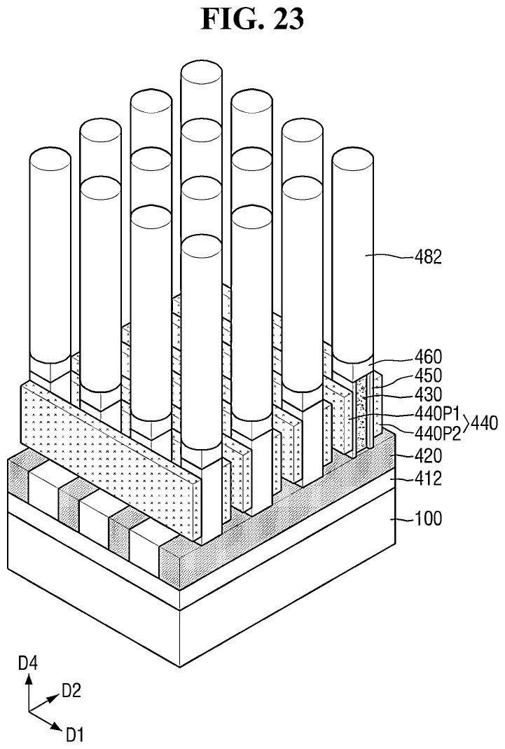

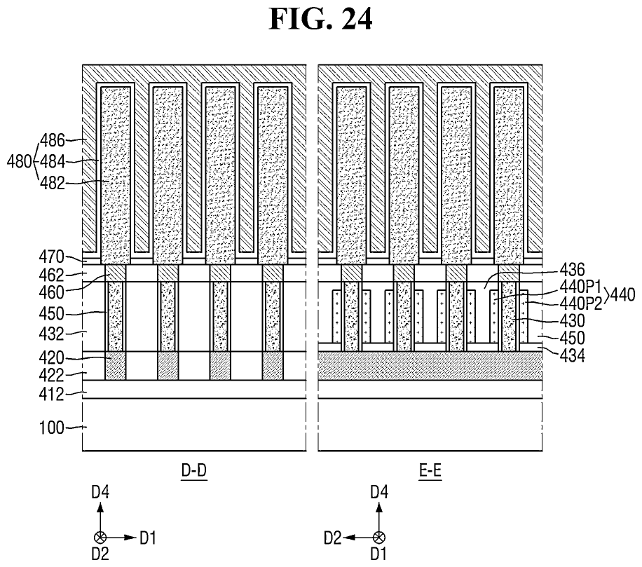

FIG. 22 is a diagram for illustrating a semiconductor memory device according to some embodiments. FIG. 23 is a diagram for illustrating a semiconductor memory device according to some embodiments. FIG. 24 is a cross-sectional view cut along lines D-D and E-E of FIG. 22.

For reference, FIG. 22 may be an enlarged view of the cell area 20 in FIG. 1.

Referring to FIG. 22 to FIG. 24, the semiconductor memory device according to some embodiments may include the substrate 100, a plurality of first conductive lines 420, a channel layer 430, a gate electrode 440, a gate insulating film 450, and a capacitor 480. The semiconductor memory device according to some embodiments may be a memory device including a vertical channel transistor (VCT). The vertical channel transistor may refer to a structure in which a channel length of the channel layer 430 extends along a vertical direction from the substrate 100.

A lower insulating layer 412 may be disposed on the substrate 100. The plurality of first conductive lines 420 disposed on the lower insulating layer 412 may be spaced apart from each other in the first direction D1 and may extend in the second direction D2. Each of a plurality of first insulating patterns 422 may be disposed on the lower insulating layer 412 so as to fill a space between adjacent ones of the plurality of first conductive lines 420. The plurality of first insulation patterns 422 may extend in the second direction D2. An upper surface of each of the plurality of first insulating patterns 422 may be disposed at the same level as that of an upper surface of each of the plurality of first conductive lines 420. Each of the plurality of first conductive lines 420 may function as a bit-line.

Each of the plurality of first conductive lines 420 may be formed of or include a doped semiconductor material, a metal, a conductive metal nitride, a conductive metal silicide, a conductive metal oxide, or a combination thereof. For example, each of the plurality of first conductive line 420 may include doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOₓ, RuOₓ, or a combination thereof. However, embodiments of the present disclosure are not limited thereto. Each of the plurality of first conductive lines 420 may include a single layer or a stack of multiple layers made of the aforementioned materials. In some embodiments, each of the plurality of first conductive lines 420 may include graphene, carbon nanotube, or a combination thereof.

The channel layers 430 may be arranged in a matrix form and may be spaced apart from each other in the first direction D1 and the second direction D2 and may be disposed on the plurality of first conductive lines 420. The channel layer 430 may have a first width along the first direction D1 and a first vertical dimension along a fourth direction D4. The first vertical dimension may be larger than the first width. For example, the first vertical dimension may be about 2 to 10 times the first width. However, embodiments of the present disclosure are not limited thereto. In this regard, the fourth direction D4 intersects the first direction D1 and the second direction D2, and may be, for example, a direction perpendicular to the upper surface of the substrate 100. A bottom portion of the channel layer 430 may function as a first source/drain area (not shown), and a top portion of the channel layer 430 may function as a second source/drain area (not shown), and a portion of the channel layer 430 between the first and second source/drain areas may function as a channel area (not shown).

In one example, the channel layer 430 may be formed of or include an oxide semiconductor. For example, the oxide semiconductor may include InₓGa_{y}Zn_{z}O, InₓGa_{y}Si_{z}O, InₓSn_{y}Zn_{z}O, InₓZn_{y}O, ZnₓO, ZnₓSn_{y}O, ZnₓO_{y}N, ZrₓZn_{y}Sn_{z}O, SnₓO, HfₓIn_{y}Zn_{z}O, GaₓZn_{y}Sn_{z}O, AlₓZn_{y}Sn_{z}O, YbₓGa_{y}Zn_{z}O, InₓGa_{y}O or combinations thereof. The channel layer 430 may include a single layer or multiple layers made of the oxide semiconductor. In some embodiments, the channel layer 430 may have a bandgap energy greater than that of silicon. For example, the channel layer 430 may have a bandgap energy of about 1.5 eV to about 5.6 eV. For example, the channel layer 430 may have optimal channel performance when it has a bandgap energy of about 2.0 eV to 4.0 eV. For example, the channel layer 430 may be made of polycrystalline or amorphous material. However, embodiments of the present disclosure are not limited thereto. In another example, the channel layer 430 may include a two-dimensional (2D) semiconductor material. For example, the 2D semiconductor material may include graphene, carbon nanotubes, or a combination thereof. In still another example, the channel layer 430 may include a silicon-based semiconductor material. The channel layer 430 may include single crystal semiconductor material. For example, the channel layer 430 may include single crystal silicon or single crystal silicon-germanium, but is not limited thereto.

The gate electrode 440 may extend in the first direction D1 and may be disposed on each of both opposing sidewalls of the channel layer 430. The gate electrode 440 may include a first sub-gate electrode 440P1 facing a first sidewall of the channel layer 430 and a second sub-gate electrode 440P2 facing a second sidewall opposite to the first sidewall of the channel layer 430. As one channel layer 430 is disposed between the first sub-gate electrode 440P1 and the second sub-gate electrode 440P2, the semiconductor memory device may have a dual gate transistor structure. However, embodiments of the present disclosure are not limited thereto, and the second sub-gate electrode 440P2 may be omitted and only the first sub-gate electrode 440P1 facing the first sidewall of the channel layer 430 may be formed to achieve a single gate transistor structure. A material of the gate electrode 440 may be the same as that of the cell gate electrode 112.

The gate insulating film 450 surrounds a sidewall of the channel layer 430 and may be interposed between the channel layer 430 and the gate electrode 440. For example, as shown in FIG. 22, an entirety of the sidewall of the channel layer 430 may be surrounded with the gate insulating film 450, or a portion of the sidewall of the gate electrode 440 may be in contact with the gate insulating film 450. In some further embodiments, the gate insulating film 450 may extend in an extension direction of the gate electrode 440, that is, the first direction D1, and only two sidewalls facing the gate electrode 440 among the sidewalls of the channel layer 430 may be in contact with the gate insulating layer 450. In some embodiments, the gate insulating film 450 may be formed of or include at least one of a silicon oxide film, a silicon oxynitride film, a film made of a high-k material having a higher dielectric constant than that of silicon oxide, or combinations thereof.

A plurality of second insulating patterns 432 may be respectively disposed on the plurality of first insulating patterns 422 and may extend along the second direction D2. The channel layer 430 may be disposed between two adjacent second insulating patterns 432 among the plurality of second insulating patterns 432. Further, a first buried layer 434 and a second buried layer 436 may be disposed between two adjacent second insulating patterns 432 and in a space between two adjacent channel layers 430. The first buried layer 434 may be disposed at a bottom portion of the space between two adjacent channel layers 430, and the second buried layer 436 may be formed on the first buried layer 434 so as to fill the remainder of the space between two adjacent channel layers 430. An upper surface of the second buried layer 436 may be coplanar with an upper surface of the channel layer 430, and the second buried layer 436 may cover an upper surface of the gate electrode 440. Alternatively, the plurality of second insulating patterns 432 may be continuous and monolithic with the plurality of first insulating patterns 422, respectively, and/or the second buried layer 436 may be continuous and monolithic with the first buried layer 434.

A capacitor contact 460 may be disposed on the channel layer 430. The capacitor contact 460 may vertically overlap the channel layer 430. The capacitor contacts 460 may be arranged in a matrix form and may be spaced apart from each other in the first direction D1 and the second direction D2. The capacitor contact 460 may be made of doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOₓ, RuOₓ, or a combination thereof. However, embodiments of the present disclosure are not limited thereto. An upper insulating layer 462 may surround a sidewall of the capacitor contact 460 and may be disposed on the plurality of second insulating patterns 432 and the second buried layer 436.

An etch stop film 470 may be disposed on the upper insulating layer 462. The capacitor 480 may be disposed on the etch stop film 470. The capacitor 480 may include a second lower electrode 482, a second capacitor dielectric film 484 and a second upper electrode 486. The second lower electrode 482 may extend through the etch stop film 470 so as to be electrically connected to an upper surface of the capacitor contact 460. The second lower electrode 482 may be formed in a pillar type extending in the fourth direction D4. However, embodiments of the present disclosure are not limited thereto. In some embodiments, the second lower electrode 482 may vertically overlap the capacitor contact 460. The second lower electrodes 482 may be arranged in a matrix form and may be spaced apart from each other in the first direction D1 and the second direction D2. Alternatively, a landing pad (not shown) may be further disposed between the capacitor contact 460 and the second lower electrode 482 so that the second lower electrodes 482 may be arranged in a hexagonal shape.

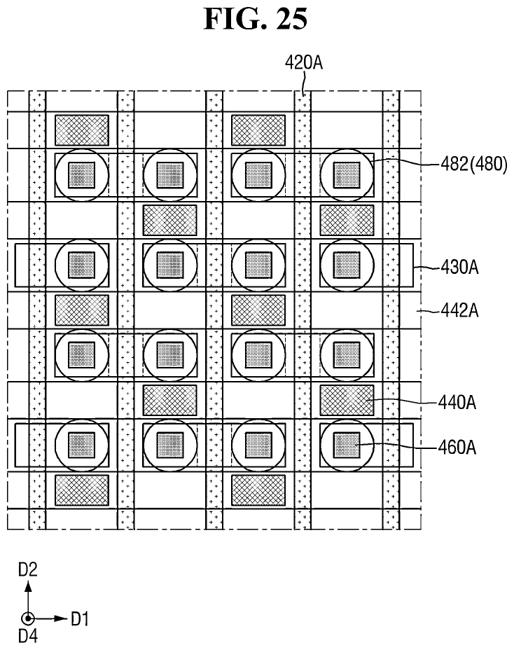

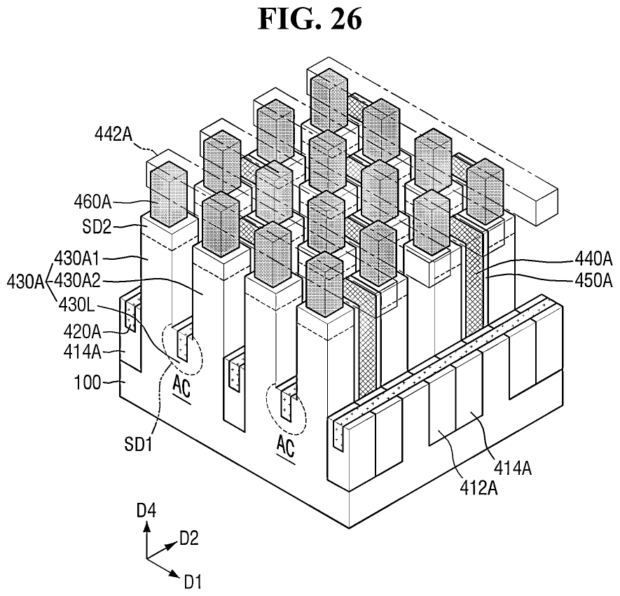

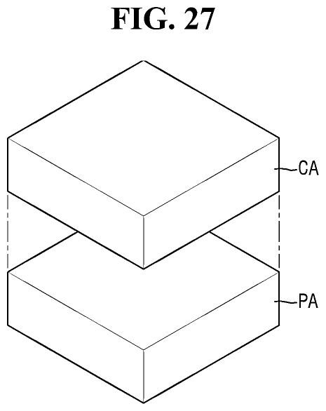

FIG. 25 is a layout diagram for illustrating a semiconductor memory device according to some embodiments. FIG. 26 is a perspective view for illustrating a semiconductor memory device according to some embodiments. FIG. 27 is a diagram for illustrating a semiconductor memory device according to some embodiments.

Referring to FIG. 25 and FIG. 26, the semiconductor memory device according to some embodiments may include the substrate 100, a plurality of first conductive lines 420A, a channel structure 430A, a contact gate electrode 440A, a plurality of second conductive lines 442A, and the capacitor 480. The semiconductor memory device according to some embodiments may be a memory device including a vertical channel transistor (VCT).

A plurality of active areas AC may be defined in the substrate 100 and by a first element isolation pattern 412A and a second element isolation pattern 414A. The channel structure 430A may be disposed in each active area AC. The channel structure 430A may include a first active pillar 430A1 and a second active pillar 430A2 extending in a vertical direction, and a connective portion 430L connected to a bottom portion of the first active pillar 430A1 and a bottom portion of the second active pillar 430A2. A first source/drain area SD1 may be disposed in the connective portion 430L. A second source/drain area SD2 may be disposed at a top portion of each of the first and second active pillars 430A1 and 430A2. Each of the first active pillar 430A1 and the second active pillar 430A2 may constitute an independent unit memory cell.

The plurality of first conductive lines 420A may extend so as to intersect the plurality of active areas AC. For example, the plurality of first conductive lines 420A may extend in the second direction D2. One first conductive line 420A of the plurality of first conductive lines 420A may be disposed on the connective portion 430L and between the first active pillar 430A1 and the second active pillar 430A2, and may be disposed on the first source/drain area SD1. Another first conductive line 420A adjacent to said one first conductive line 420A may be disposed between two channel structures 430A adjacent to each other in the first direction D1. One first conductive line 420A among the plurality of first conductive lines 420A may function as a common bit-line of two unit memory cells respectively including the first active pillar 430A1 and the second active pillar 430A2 respectively disposed on both opposing sides of said one first conductive line 420A.

One contact gate electrode 440A may be disposed between two channel structures 430A adjacent to each other in the second direction D2. For example, the contact gate electrode 440A may be disposed between the first active pillar 430A1 included in one channel structure 430A and the second active pillar 430A2 of another channel structure 430A adjacent thereto. One contact gate electrode 440A may be shared by the first active pillar 430A1 and the second active pillar 430A2 respectively disposed on both sidewalls thereof. A gate insulating layer 450A may be disposed between the contact gate electrode 440A and the first active pillar 430A1 and between the contact gate electrode 440A and the second active pillar 430A2. The plurality of second conductive lines 442A may extend in the first direction D1 and may be disposed on an upper surface of the contact gate electrode 440A. Each of the plurality of second conductive lines 442A may function as a word-line of the semiconductor memory device.

A capacitor contact 460A may be disposed on the channel structure 430A. The capacitor contact 460A may be disposed on the second source/drain area SD2. The capacitor 480 may be disposed on the capacitor contact 460A.

Referring to FIG. 27, the semiconductor memory device according to some embodiments may have a COP (Cell on Peri) structure in which a cell array area CA is disposed on a peripheral structure area PA.

The peripheral structure area PA may correspond to the peripheral area 24 of FIG. 1 and FIG. 4. The cell array area CA may include the vertical channel transistor (VCT) of FIG. 22 to FIG. 26.

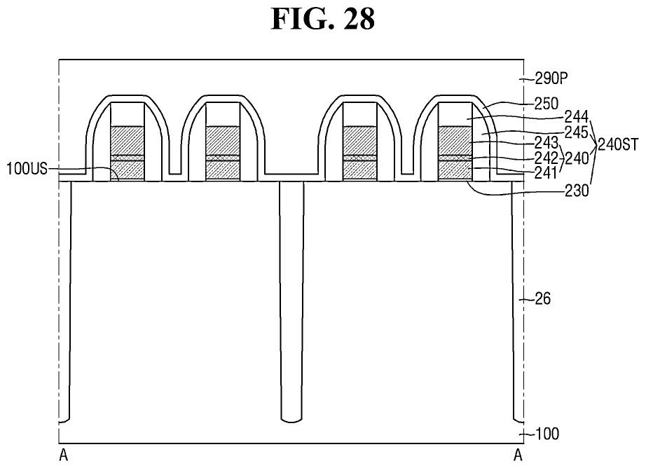

FIG. 28 to FIG. 34 are diagrams of intermediate structures corresponding to intermediate steps for illustrating a method for manufacturing a semiconductor memory device according to some embodiments. In the description of the manufacturing method, descriptions duplicate with those as set forth above using FIG. 1 to FIG. 8 are briefly set forth or omitted.

Referring to FIG. 1 and FIG. 28, the substrate 100 including the cell area 20, the peripheral area 24, and the cell area isolation film 22 is provided.

On the substrate 100 and in the peripheral area 24, the peripheral gate structure 240ST may be formed. The peripheral gate structure 240ST may include the peripheral gate insulating film 230, the peripheral gate conductive film 240, the peripheral capping film 244, and the peripheral spacer 245.

Subsequently, the lower etch stop film 250 may be formed on the substrate 100. The lower etch stop film 250 may be formed on the peripheral gate structure 240ST. The lower etch stop film 250 may be formed along the profile of the peripheral gate structure 240ST.

Subsequently, a first pre-interlayer insulating film 290P may be formed on the lower etch stop film 250. The first pre-interlayer insulating film 290P may entirely cover the lower etch stop film 250. The first pre-interlayer insulating film 290P may be formed of or include, for example, a silicon oxide-based insulating material.

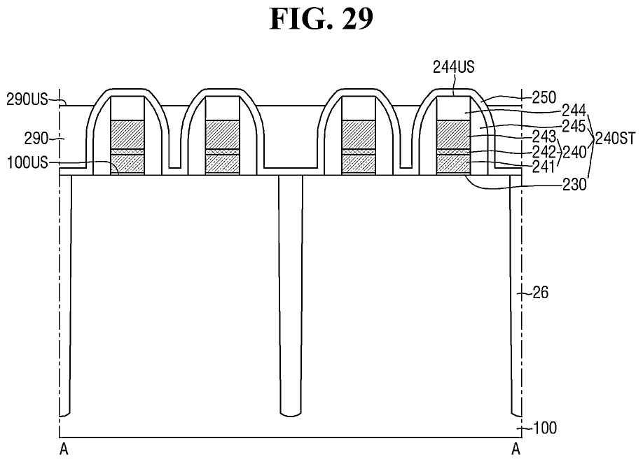

Referring to FIG. 29, a portion of the first pre-interlayer insulating film 290P disposed on the upper surface of the peripheral gate structure 240ST may be removed, such that a portion of the lower etch stop film 250 disposed on the upper surface of the peripheral gate structure 240ST may be exposed.

For example, using a chemical mechanical polishing process (CMP), a portion of the first pre-interlayer insulating film 290P may be removed. That is, using the chemical mechanical polishing process (CMP), the portion of the first pre-interlayer insulating film 290P disposed on the upper surface of the peripheral gate structure 240ST may be removed.

Subsequently, another portion of the first pre-interlayer insulating film 290P may be removed through an etch-back process. Thus, the first peripheral interlayer insulating film 290 may be formed on the lower etch stop film 250.

The vertical level of the upper surface 290US of the first peripheral interlayer insulating film 290 may be lower than that of the upper surface 244US of the peripheral capping film 244.

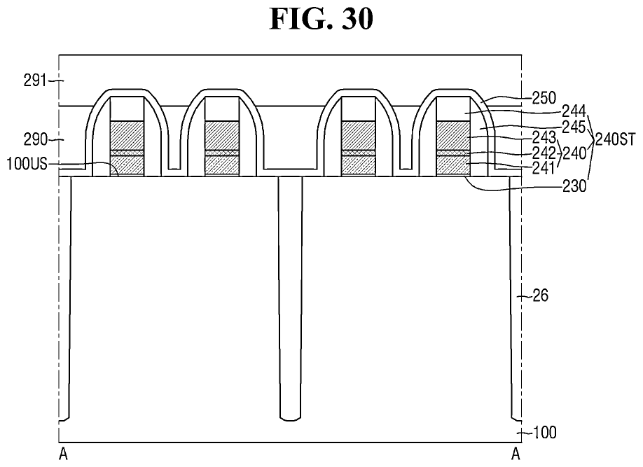

Referring to FIG. 30, the inserted interlayer insulating film 291 may be formed on the first peripheral interlayer insulating film 290.

The inserted interlayer insulating film 291 may be formed on the portion of the lower etch stop film 250 that protrudes upwardly beyond the first peripheral interlayer insulating film 290. The inserted interlayer insulating film 291 is formed not only on the peripheral area 24 but also on the cell area (20 in FIG. 1).

Although not shown, the bit-line structure (140ST in FIG. 5) extending in an elongate manner in the second direction D2 may be formed on the cell area (20 in FIG. 1). The cell line spacer (150 in FIG. 5) may be formed on the sidewall of the bit-line structure 140ST. The fence pattern (170 in FIG. 6) may be formed between bit-line structures 140ST adjacent to each other in the first direction D1. After forming the fence pattern 170, the storage contacts (120 in FIG. 5 and FIG. 6) may be respectively formed between cell conductive lines (140 in FIG. 5) adjacent to each other and between fence patterns 170 adjacent to each other in the second direction D2.

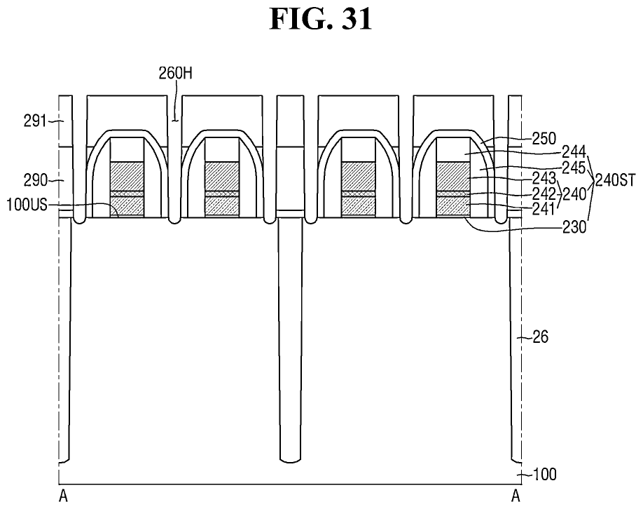

Referring to FIG. 31, a peripheral contact plug hole 260H may be formed within the inserted interlayer insulating film 291 and the first peripheral interlayer insulating film 290.

The peripheral contact plug hole 260H may extend through the inserted interlayer insulating film 291 and the first peripheral interlayer insulating film 290. The peripheral contact plug hole 260H may expose a portion of the substrate 100 in the peripheral area (24 in FIG. 1).

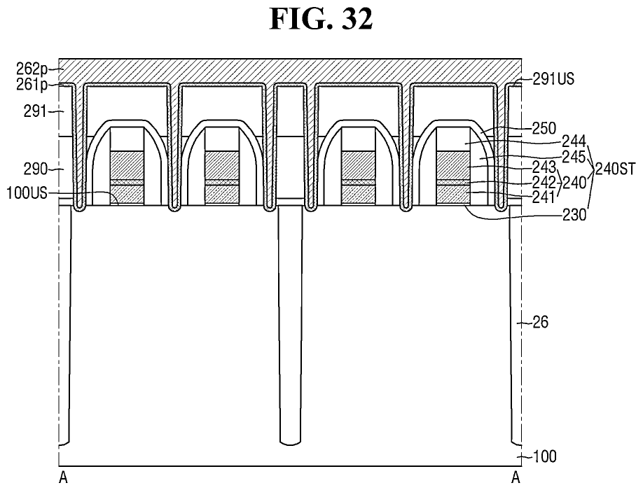

Referring to FIG. 31 and FIG. 32, a pre-barrier conductive film 261p may be formed along a profile of the peripheral contact plug hole 260H and the upper surface 291US of the inserted interlayer insulating film 291.

A pre-filling conductive film 262p may be formed on the pre-barrier conductive film 261p. The pre-filling conductive film 262p may fill the peripheral contact plug hole 260H. The pre-filling conductive film 262p may be formed on the upper surface 291US of the inserted interlayer insulating film 291.

The pre-barrier conductive film 261p and the pre-filling conductive film 262p may also be formed on the cell area (20 in FIG. 1).

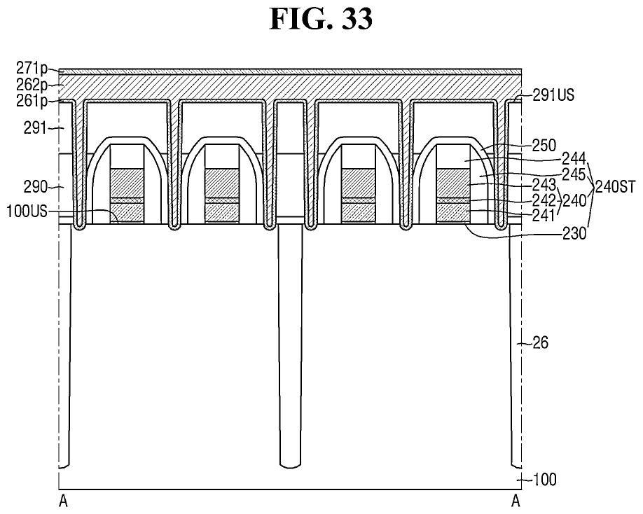

Referring to FIG. 33, a first pre-line capping film 271p may be formed on the pre-filling conductive film 262p.

The first pre-line capping film 271p may also be formed on the cell area (20 in FIG. 1).

In one example, using a vapor deposition process, the first pre-line capping film 271p may be formed on the pre-filling conductive film 262p. In another example, the first pre-line capping film 271p may be formed by nitriding a portion of the pre-filling conductive film 262p. For example, a portion of the pre-filling conductive film 262p may be converted to a nitride through a plasma nitriding process.

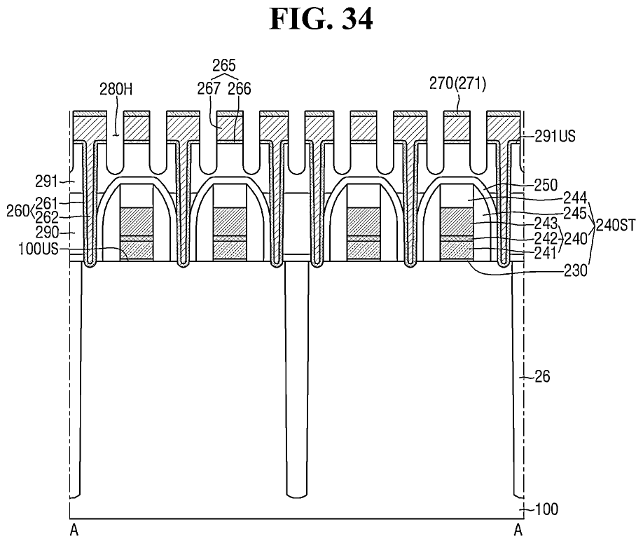

Referring to FIG. 33 and FIG. 34, a line isolation hole 280H may be formed in the pre-barrier conductive film 261p, the pre-filling conductive film 262p, and the first pre-line capping film 271p.

A portion of the line isolation hole 280H may be formed within the inserted interlayer insulating film 291.

The pre-barrier conductive film 261p, the pre-filling conductive film 262p and the first pre-line capping film 271p may be isolated from each other via the line isolation hole 280H. Thus, the first peripheral wiring capping film 271, the peripheral wiring line 265, and peripheral contact plug 260 may be formed.

Next, referring to FIG. 4, the peripheral wiring isolation pattern 280 may be formed within the line isolation hole 280H.

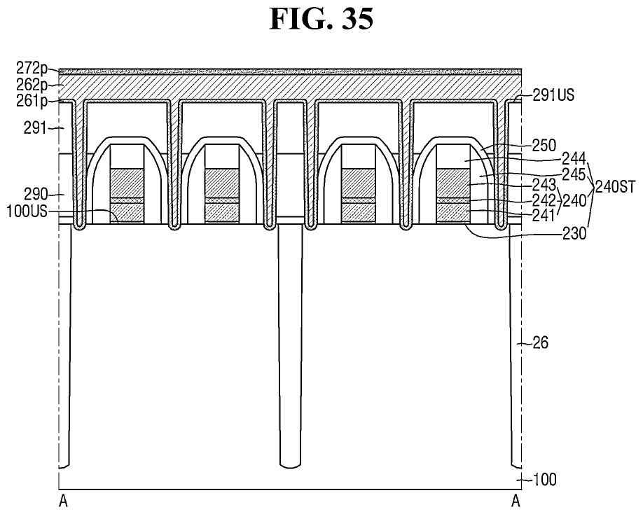

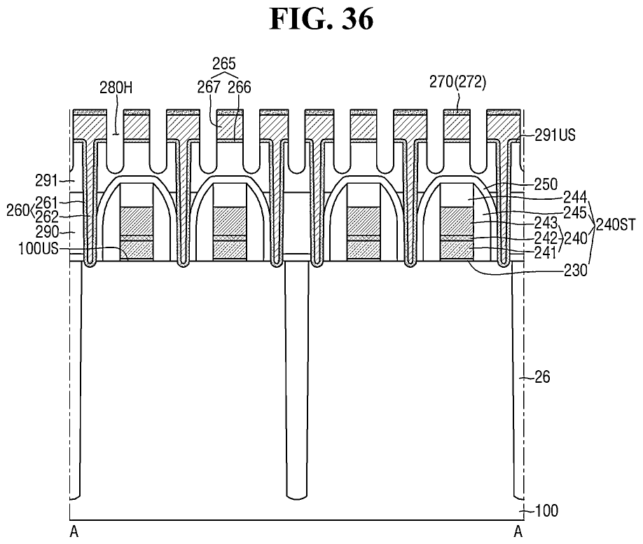

FIG. 35 and FIG. 36 are diagrams of intermediate structures corresponding to intermediate steps of a semiconductor memory device manufacturing method according to some embodiments. FIG. 35 may be a manufacturing process that proceeds after FIG. 32.

Referring to FIG. 35, a second pre-line capping film 272p may be formed on the pre-filling conductive film 262p.

The second pre-line capping film 272p may also be formed on the cell area (20 in FIG. 1). For example, using a vapor deposition process, the second pre-line capping film 272p may be formed on the pre-filling conductive film 262p.

Referring to FIG. 35 and FIG. 36, the line isolation hole 280H may be formed within the pre-barrier conductive film 261p, the pre-filling conductive film 262p, and the second pre-line capping film 272p.

A portion of the line isolation hole 280H may be formed within the inserted interlayer insulating film 291.

The pre-barrier conductive film 261p, the pre-filling conductive film 262p and the second pre-line capping film 272p may be isolated from each other via the line isolation hole 280H. Thus, the second peripheral wiring capping film 272, the peripheral wiring line 265, and the peripheral contact plug 260 may be formed.

Although embodiments of the present disclosure have been described with reference to the accompanying drawings, embodiments of the present disclosure are not limited to the above embodiments, but may be implemented in various different forms. A person skilled in the art may appreciate that the present disclosure may be practiced in other concrete forms without changing the technical spirit or essential characteristics of the present disclosure. Therefore, it should be appreciated that the embodiments as described above are not restrictive but illustrative in all respects.

In concluding the detailed description, those skilled in the art will appreciate that many variations and modifications may be made to the preferred embodiments without substantially departing from the principles of the present inventive concept. Therefore, the disclosed preferred embodiments of the invention are used in a generic and descriptive sense only and not for purposes of limitation.

What is claimed is:

1. A semiconductor memory device comprising:
a substrate including a cell area and a peripheral area defined around the cell area, wherein the cell area includes a cell active area defined by a cell element isolation film;
a bit-line on the cell area of the substrate;
a peripheral gate on the peripheral area of the substrate, the peripheral gate including a peripheral gate conductive film;
peripheral wiring lines on the peripheral gate, wherein each of the peripheral wiring lines includes a peripheral wiring extension line made of a metal;
peripheral wiring capping films respectively in contact with the peripheral wiring extension lines, wherein each of the peripheral wiring capping films includes an upper surface and a lower surface opposite to the upper surface; and
a peripheral wiring isolation pattern isolating adjacent peripheral wiring lines from each other, and contacting sidewalls of the isolated peripheral wiring lines,
wherein the lower surface of each of the peripheral wiring capping films faces the substrate and contacts an upper surface of a respective peripheral wiring extension line, and
wherein a height from an upper surface of the substrate to the upper surface of each of the peripheral wiring extension lines is smaller than a height from the upper surface of the substrate to an upper surface of the peripheral wiring isolation pattern.

2. The semiconductor memory device of claim 1, wherein the peripheral wiring capping films include a metal nitride.

3. The semiconductor memory device of claim 2, wherein the peripheral wiring capping films include a nitride of the metal included in the peripheral wiring extension lines.

4. The semiconductor memory device of claim 1, wherein the peripheral wiring capping films include a silicon nitride-based insulating material.

5. The semiconductor memory device of claim 1, wherein the height from the upper surface of the substrate to the upper surface of the peripheral wiring isolation pattern is equal to a height from the upper surface of the substrate to an upper surface of each of the peripheral wiring capping films.

6. The semiconductor memory device of claim 1, wherein the height from the upper surface of the substrate to the upper surface of the peripheral wiring isolation pattern is smaller than a height from the upper surface of the substrate to an upper surface of each of the peripheral wiring capping films.

7. The semiconductor memory device of claim 1, wherein a width of the lower surface of each of the peripheral wiring capping films is equal to a width of the upper surface of each of the peripheral wiring extension lines.

8. The semiconductor memory device of claim 1, further comprising:
an etch stop film extending along the upper surface of the peripheral wiring isolation pattern and the upper surface of each of the peripheral wiring capping films; and
a peripheral upper interlayer insulating film on the etch stop film.

9. The semiconductor memory device of claim 8, wherein the etch stop film does not contact the sidewalls of the peripheral wiring lines.

10. The semiconductor memory device of claim 1, further comprising:
storage contacts connected to the cell active area;
storage pads connected to the storage contact;
a pad isolation pattern isolating adjacent storage pads from each other; and
data storage patterns connected to the storage pads,
wherein a height from the upper surface of the substrate to an upper surface of the storage pads is smaller than a height from the upper surface of the substrate to an upper surface of the pad isolation pattern.

11. The semiconductor memory device of claim 10, further comprising a storage pad capping film between the storage pads and the data storage pattern, the storage pad capping film being in contact with the upper surface of the storage pads,
wherein the data storage patterns are in contact with the storage pad capping film, and
wherein the storage pad capping film includes a metal nitride.

12. The semiconductor memory device of claim 10, wherein the data storage patterns are in contact with the upper surface of the storage pads.

13. A semiconductor memory device comprising:
a substrate including a cell area and a peripheral area defined around the cell area, wherein the cell area includes a cell active area defined by a cell element isolation film;
a bit-line on the cell area of the substrate;
a peripheral gate on the peripheral area of the substrate, the peripheral gate including a peripheral gate conductive film;
peripheral wiring lines on the peripheral gate, wherein each of the peripheral wiring lines includes a peripheral wiring extension line made of a metal;
peripheral wiring capping films respectively in contact with the peripheral wiring extension lines, wherein each of the peripheral wiring capping films includes an upper surface and a lower surface opposite to the upper surface; and
a peripheral wiring isolation pattern isolating adjacent peripheral wiring lines from each other, and contacting sidewalls of the isolated peripheral wiring lines,
wherein the lower surface of each of the peripheral wiring capping films faces the substrate and contacts an upper surface of a respective peripheral wiring extension line without contacting an upper surface of the peripheral wiring isolation pattern.

14. The semiconductor memory device of claim 13, wherein each of the peripheral wiring capping films extends without contacting the sidewalls of the peripheral wiring lines.

15. The semiconductor memory device of claim 13, wherein the peripheral wiring capping films include nitride of the metal included in the peripheral wiring extension lines.

16. The semiconductor memory device of claim 13, wherein the peripheral wiring capping films include a silicon nitride-based insulating material.

17. The semiconductor memory device of claim 13, further comprising:
storage contacts connected to the cell active area;
storage pads connected to the storage contact;
a pad isolation pattern isolating adjacent storage pads from each other; and
data storage patterns connected to the storage pads,
wherein a height from an upper surface of the substrate to an upper surface of the storage pads is smaller than a height from the upper surface of the substrate to an upper surface of the pad isolation pattern.

18. The semiconductor memory device of claim 17, further comprising an etch stop film extending along an upper surface of the peripheral wiring isolation pattern, the upper surface of each of the peripheral wiring capping films, and the upper surface of the pad isolation pattern.

19. A semiconductor memory device comprising:
a substrate including a cell area and a peripheral area defined around the cell area, wherein the cell area includes a cell active area defined by a cell element isolation film;
a bit-line on the cell area of the substrate;
a peripheral gate on the peripheral area of the substrate, the peripheral gate including a peripheral gate conductive film;
peripheral wiring lines on the peripheral gate, wherein each of the peripheral wiring lines includes a peripheral wiring extension line made of a metal;
peripheral wiring capping films respectively in contact with the peripheral wiring extension lines, wherein each of the peripheral wiring capping films includes an upper surface and a lower surface opposite to the upper surface;
a peripheral wiring isolation pattern isolating adjacent peripheral wiring lines from each other, and contacting sidewalls of the isolated peripheral wiring lines,
storage contacts connected to the cell active area;
storage pads connected to the storage contact, wherein each of the storage pads includes a storage pad plug film, wherein each of the storage pad plug films is made of the same metal as the metal of the peripheral wiring extension lines;
a pad isolation pattern isolating adjacent storage pads from each other;
an etch stop film extending along an upper surface of the peripheral wiring isolation pattern, the upper surface of each of the peripheral wiring capping films, and an upper surface of the pad isolation pattern; and
a data storage pattern extending through the etch stop film to be connected to the storage pad plug films,
wherein the lower surface of each of the peripheral wiring capping films faces the substrate and contacts an upper surface of a respective peripheral wiring extension line, and
wherein a height from an upper surface of the substrate to the upper surface of each of the peripheral wiring capping films is equal to a height from the upper surface of the substrate to the upper surface of the peripheral wiring isolation pattern.

20. The semiconductor memory device of claim 19, wherein the peripheral wiring capping films include one of a metal nitride and a silicon nitride series insulating material, and
wherein the metal nitride is a nitride of the metal included in the peripheral wiring extension lines.
